(19) United States
(12) Patent Application Publication
(10) Pub. No.: US 2025/0359167 A1
(43) Pub. Date: Nov. 20, 2025

(54) Gate Stack for Multigate Device

(71) Applicant: Taiwan Semiconductor Manufacturing Company, Ltd., Hsin-Chu (TW)

(72) Inventors: Chih-Wei LEE, New Taipei City (TW); Hsin-Han TSAI, Hsinchu (TW); Tai-Wei HWANG, Kinmen County (TW)

(21) Appl. No.: 19/284,161

(22) Filed: Jul. 29, 2025

Related U.S. Application Data
(63) Continuation of application No. 18/405,430, filed on Jan. 5, 2024.
(60) Provisional application No. 63/578,406, filed on Aug. 24, 2023.

(51) Int. Cl. H10D 30/67; H10D 30/01; H10D 30/43; H10D 62/10; H10D 64/01; H10D 84/01; H10D 84/03; H10D 84/85

(52) U.S. Cl. CPC H10D 30/6735; H10D 30/014; H10D 30/43; H10D 30/6757; H10D 62/121; H10D 64/017; H10D 84/0167; H10D 84/038; H10D 84/85

(57) ABSTRACT

An exemplary gate stack includes a gate dielectric (e.g., a high-k dielectric layer over an interfacial layer) and a gate electrode (e.g., a work function layer over the high-k dielectric layer, a cap over the work function layer, and a bulk fill layer over the cap). The gate stack wraps and/or surrounds a first semiconductor layer disposed over a second semiconductor layer. The gate dielectric and the work function layer (and not the cap and/or the bulk fill layer) fill a space between the first semiconductor layer and the second semiconductor layer. A ratio of oxygen in outer portions of the gate stack to inner portions of the gate stack may be about 1 to about 1.25. A thickness of the work function layer at inner portions of the gate stack may be less than a thickness of the work function layer at outer portions of the gate stack.

This is a continuation application of U.S. patent application Ser. No. 18/405,430, filed Jan. 5, 2024, which is a non-provisional application of and claims benefit of U.S. Provisional Patent Application Ser. No. 63/578,406, filed Aug. 24, 2023, the entire disclosures of which are incorporated herein by reference.

### BACKGROUND

Multigate devices have been introduced to meet the semiconductor integrated circuit (IC) industry's ever-increasing demand for smaller and faster electronic devices that can simultaneously support a greater number of increasingly complex and sophisticated functions. A multigate device has a gate that extends, partially or fully, around a channel region to provide access to the channel region on at least two sides. Exemplary multi-gate devices include fin-like field effect (FinFET) transistors, gate-all-around (GAA) transistors (e.g., nanostructure-based (e.g., nanowire, nanosheet, or nanobar) transistors), other three-dimensional (3D) transistors (e.g., forksheet transistors), or a combination thereof. Multigate devices enable aggressive scaling down of IC technologies and have been observed to improve gate control, increase gate-channel coupling, reduce off-state current, and reduce short-channel effects (SCEs), while seamlessly integrating with conventional IC manufacturing processes.

However, as IC technology nodes continue to scale, fabricating gate stacks around a channel region of a multigate device has become challenging. For example, a gate stack of a multigate device is often formed using a gate replacement process that includes removing a dummy gate to form a gate opening that exposes a channel layer(s) and filling the gate opening with various gate layers, such as a gate dielectric and a gate electrode. Decreasing device feature sizes have led to decreasing gate opening dimensions and thus reduced gate stack volume. As a result, gate layers wrapping the channel layer(s) may easily fill the gate opening and/or spaces between adjacent channel layers, which leaves limited room in the gate opening for fine tuning threshold voltage (Vt) of the multigate device, for example, by using multiple work function layers and/or a thicker work function layer. Various combinations and/or configurations of layers have been explored in gate stacks to maximize multigate device performance while minimizing performance mismatch, such as threshold voltage variations (σVt), between multigate devices of an IC, such as those forming a memory. Although existing gate stack configurations for multigate devices and methods of fabrication thereof have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a gate stack of a device, in portion or entirety, according to various aspects of the present disclosure.

FIG. 2 is a perspective view of a device, such as a transistor, in portion or entirety, at a fabrication stage associated with a method for fabricating a gate stack of a device, such as the method of FIG. 1, according to various aspects of the present disclosure.

FIGS. 3A-14A and FIGS. 3B-14B are cross-sectional views of a device, such as a transistor, in portion or entirety, at various fabrication stages associated with the method for fabricating a gate stack of FIG. 1, according to various aspects of the present disclosure.

FIG. 15A and FIG. 15B are cross-sectional views of a device, such as a transistor, in portion or entirety, having a gate stack, which may be fabricated by the method of FIG. 1, according to various aspects of the present disclosure.

FIG. 16A and FIG. 16B are energy-dispersive x-ray spectroscopy (EDX) maps of oxygen in inner regions and outer regions of a gate stack having different configurations, according to various aspects of the present disclosure.

FIG. 17 is a cross-sectional view of a stacked device structure, in portion or entirety, according to various aspects of the present disclosure.

### DETAILED DESCRIPTION

The present disclosure relates generally to integrated circuit (IC) devices, and more particularly, to gate stacks of transistors and methods of fabrication thereof.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Multigate devices, such as fin-like field effect transistors (FinFETs), gate-all-around (GAA) transistors, forksheet transistors, and other non-planar transistors, have gained popularity due to their enhanced performance compared to conventional planar transistors. As multigate device dimensions shrink to facilitate further IC technology node scaling, conventional multigate device fabrication methods face challenges. For example, unintentional and/or undesirable oxidation of gate stack layers, such as a work function layer and/or a gate dielectric layer, during a gate replacement process can lead to performance degradations, such as slower device speed and/or or threshold voltage (Vₜ) variation. This problem is exacerbated for certain IC applications, such as in static random-access memory (SRAM) devices, where n-type transistor performance may be more important than p-type transistor performance.

TO address these challenges, the present disclosure proposes a gate stack and corresponding gate stack fabrication method that reduces oxygen differences between a gate stack's inner portions (e.g., inner film stacks between channel layers) and outer portions (e.g., outer film stacks that are not between the channel layers). For example, the proposed gate stack omits a cap, such as an ex-situ cap, from inner regions thereof, configures a work function layer thereof with different thicknesses in the inner regions and the outer regions, lowers an aluminum content of the work function layer, or a combination thereof. As described herein, because such gate stack configuration accounts and/or compensates for oxygen diffusion/migration that occurs during processing (such as that which occurs when forming the cap), oxygen differences are reduced between the inner regions and the outer regions of the proposed gate stack, thereby improving device reliability and/or performance, for example, by providing faster device speeds and/or smaller threshold voltage variations. Details of improved gate stacks for multigate devices and methods of fabrication and/or design thereof are described herein.

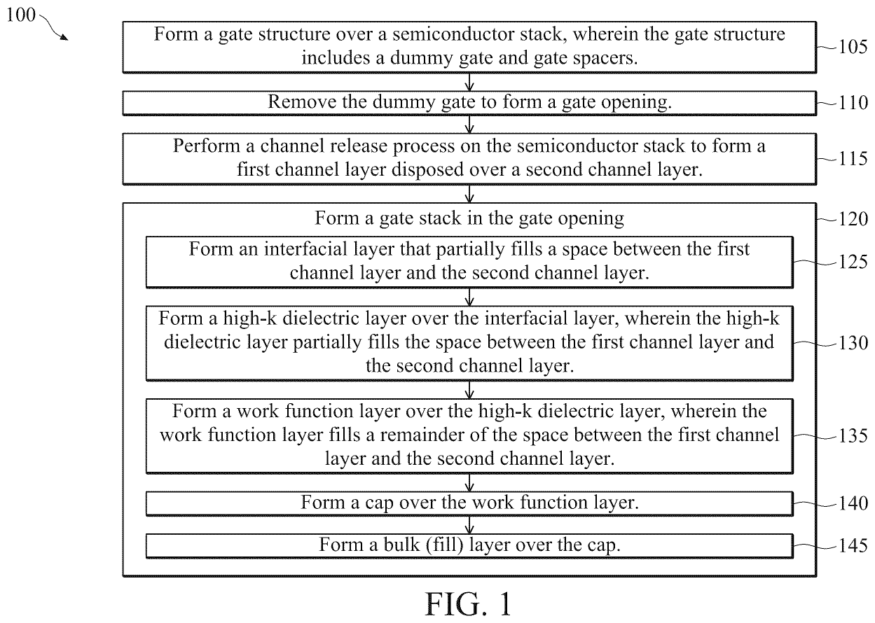

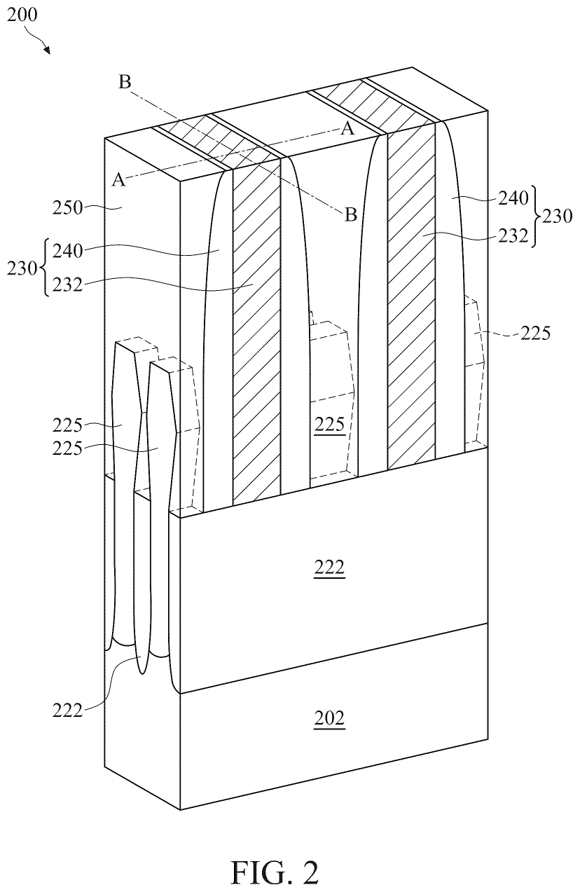

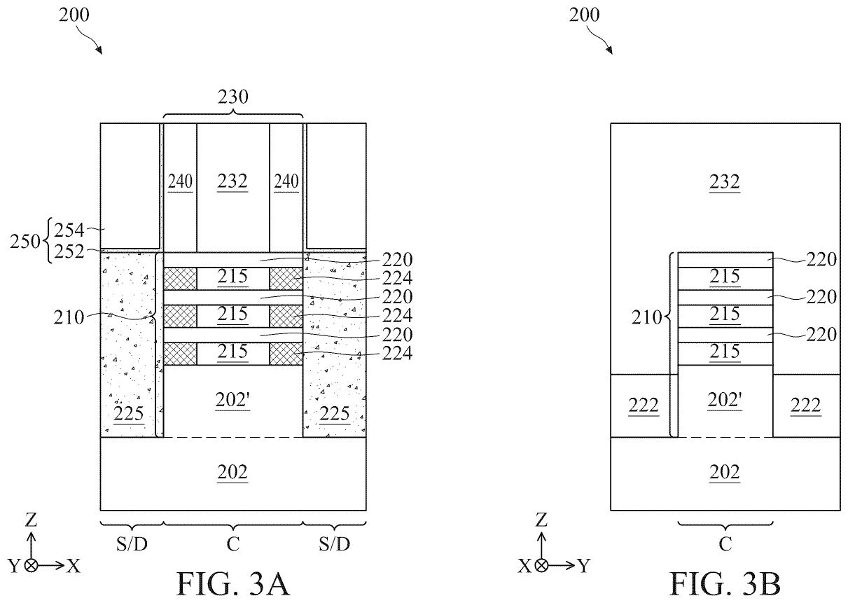

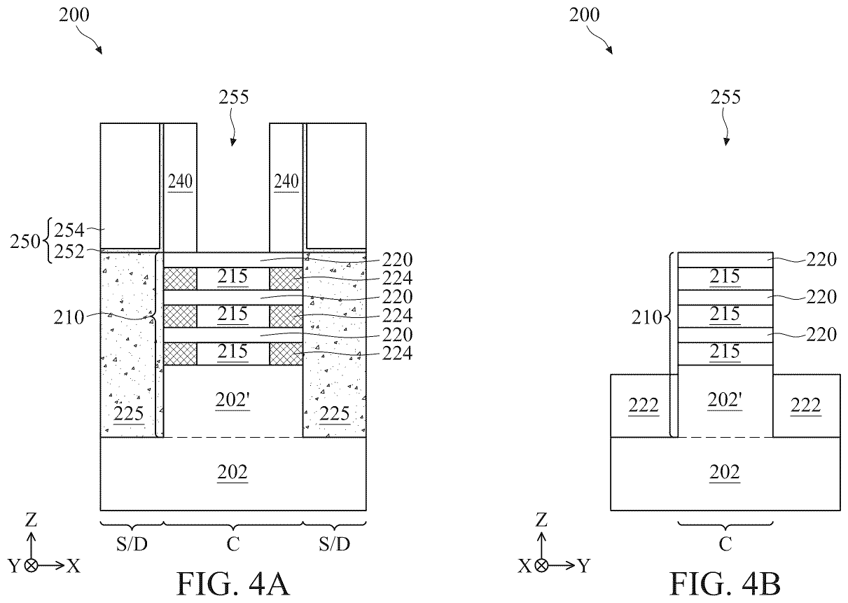

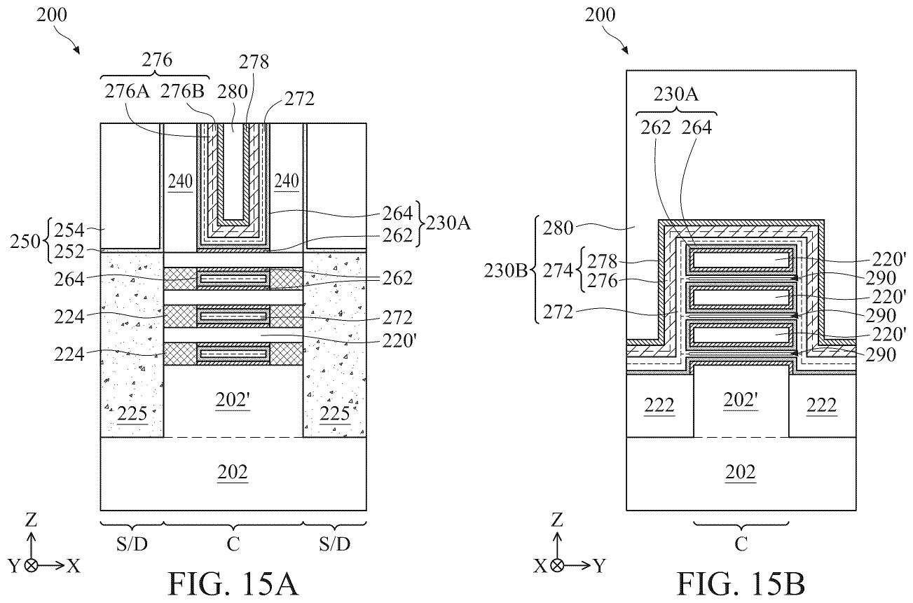

FIG. 1 is a flow chart of a method 100 for fabricating a gate stack of a device, in portion or entirety, according to various aspects of the present disclosure. FIG. 2 is a perspective view of a device 200, in portion or entirety, at a fabrication stage associated with a method for fabricating a gate stack, such as method 100 of FIG. 1, according to various aspects of the present disclosure. FIGS. 3A-14A and FIGS. 3B-14B are cross-sectional views of device 200, in portion or entirety, at various fabrication stages associated with method 100 of FIG. 1, according to various aspects of the present disclosure. FIG. 3A and FIG. 3B are cross-sectional views of device 200 (e.g., a transistor) along line A-A and line B-B, respectively, of FIG. 2, FIGS. 4A-14A are cross-sectional views of device 200 along line A-A of FIG. 2 at subsequent fabrication stages of method 100 of FIG. 1, and FIGS. 4B-14B are cross-sectional views of device 200 along line B-B of FIG. 2 at subsequent fabrication stages of method 100 of FIG. 1. FIG. 15A and FIG. 15B are cross-sectional views of device 200 having a different configuration of the gate stack, which may be fabricated by method 100 of FIG. 1, according to various aspects of the present disclosure. FIG. 1, FIG. 2, FIGS. 3A-14A, FIGS. 3B-14B, FIG. 15A, and FIG. 15B are discussed concurrently herein for ease of description and understanding. FIG. 1, FIG. 2, FIGS. 3A-14A, FIGS. 3B-14B, FIG. 15A, and FIG. 15B have been simplified for the sake of clarity to better understand the inventive concepts of the present disclosure. Additional steps may be provided before, during, and after method 100 of FIG. 1, and some of the steps described may be moved, replaced, or eliminated for additional embodiments of method 100 of FIG. 1. Additional features may be added in device 200, and some of the features described below may be replaced, modified, or eliminated in other embodiments of device 200.

Turning to FIG. 1, FIG. 2, FIG. 3A, and FIG. 3B, method 100 at block 105 includes forming a gate structure over a semiconductor stack. The gate structure includes a dummy gate and gate spacers. This may include receiving and/or forming a device precursor that includes a substrate (wafer) 202, a semiconductor stack 210 (depicted as having a mesa 202′ (i.e., a patterned, projecting portion of substrate 202), semiconductor layers 215, and semiconductor layers 220), a substrate isolation structure 222, inner spacers 224, source/drains 225, a gate structure 230 (depicted as having a dummy gate 232 and gate spacers 240), and a dielectric layer 250. Semiconductor stack 210 is in a channel region C of device 200, and source/drains 225 are in source/drain regions S/D of device 200. In FIG. 3A (e.g., an X-Z cross-sectional view), semiconductor layers 220 and mesa 202′ extend along the x-direction between source/drains 225, inner spacers 224 are between semiconductor layers 215 and source/drains 225, and gate structure 230 is disposed over a top of semiconductor stack 210 and between source/drains 225. In FIG. 3B (e.g., a Y-Z cross-sectional view), gate structure 230 is on a top and sides of semiconductor stack 210, and gate structure 230 wraps semiconductor stack 210.

Substrate 202 includes an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, substrate 202 is a silicon substrate. In some embodiments, substrate 202 is a semiconductor-on-insulator substrate, such as a silicon-on-insulator (SOI) substrate, a silicon germanium-on-insulator (SGOI) substrate, or a germanium-on-insulator (GOI) substrate. Substrate 202 (and mesa 202′) may include various doped regions, such as p-type doped regions (e.g., p-wells), n-type doped regions (e.g., n-wells), or a combination thereof. N-type doped regions include n-type dopants, such as phosphorus, arsenic, other n-type dopant, or a combination thereof. P-type doped regions include p-type dopants, such as boron, indium, other p-type dopant, or a combination thereof. In some embodiments, the doped regions include a combination of p-type dopants and n-type dopants. The doped regions may be formed directly on and/or in substrate 202, for example, providing a p-well structure, an n-well structure, a dual-well structure, a raised structure, other suitable structure, or a combination thereof. In some embodiments, substrate 202, mesa 202′, and semiconductor layers thereover include an n-well, such as where device 200 is a p-type transistor, or a p-well, such as where device 200 is an n-type transistor.

Semiconductor stack 210 extends along the x-direction, having a length along the x-direction, a width along a y-direction, and a height along a z-direction. Semiconductor layers 215 and semiconductor layers 220 are stacked vertically (e.g., along the z-direction) in an interleaving and/or alternating configuration from a top surface of substrate 202. A composition of semiconductor layers 215 is different than a composition of semiconductor layers 220 to achieve etching selectivity and/or different oxidation rates during subsequent processing. For example, semiconductor layers 215 and semiconductor layers 220 include different materials, constituent atomic percentages, constituent weight percentages, thicknesses, or a combination thereof to achieve desired etching selectivity during an etching process, such as an etch process implemented to form suspended channel layers in channel region C. In some embodiments, semiconductor layers 215 include silicon germanium, semiconductor layers 220 include silicon, and a silicon etch rate of semiconductor layers 220 is different than a silicon germanium etch rate of semiconductor layers 215 to a given etchant. In some embodiments, semiconductor layers 215 and semiconductor layers 220 include the same material but different constituent atomic percentages to achieve etching selectivity. For example, semiconductor layers 215 and semiconductor layers 220 include silicon germanium with different silicon atomic percentages and/or different germanium atomic percentages. The present disclosure contemplates semiconductor layers 215 and semiconductor layers 220 having any combination of semiconductor materials that provides desired etching selectivity, desired oxidation rate differences, desired performance characteristics (e.g., materials that maximize current flow), or a combination thereof, including any of the semiconductor materials disclosed herein.

Substrate isolation structure 222 electrically isolates active device regions and/or passive device regions of device 200 from one another. For example, substrate isolation structure 222 separates and electrically isolates an active region of device 200 (for example, semiconductor stack 210 and/or source/drains 225 thereof) from other device regions and/or devices. Substrate isolation structure 222 includes silicon oxide, silicon nitride, silicon oxynitride, other suitable isolation material (including, for example, silicon, oxygen, nitrogen, carbon, other suitable isolation constituent, etc.), or a combination thereof. Substrate isolation structure 222 may have a multilayer structure. For example, substrate isolation structure 222 may include a bulk dielectric (e.g., an oxide layer) over a dielectric liner (including, for example, silicon nitride, silicon oxide, silicon oxynitride, silicon oxycarbonitride, or a combination thereof). In another example, substrate isolation structure 222 may include a dielectric layer over a doped liner, such as a boron silicate glass (BSG) liner and/or a phosphosilicate glass (PSG) liner. Dimensions and/or characteristics of substrate isolation structure 222 are configured to provide a shallow trench isolation (STI) structure, a deep trench isolation (DTI) structure, a local oxidation of silicon (LOCOS) structure, other suitable isolation structure, or a combination thereof. In the depicted embodiment, substrate isolation structure 222 may be an STI.

Inner spacers 224 are disposed under gate spacers 240 and along sidewalls of semiconductor layers 215. Inner spacers 224 are disposed between and separate semiconductor layers 215 and source/drains 225. Inner spacers 224 are further disposed between adjacent semiconductor layers 220 and between bottommost semiconductor layer 220 and mesa 202′. Inner spacers 224 include a dielectric material that includes silicon, oxygen, carbon, nitrogen, other suitable constituent, or a combination thereof, such as silicon nitride, silicon oxynitride, silicon carbide, silicon oxycarbide, silicon oxycarbonitride, etc. In some embodiments, inner spacers 224 include a low-k dielectric material. In some embodiments, dopants (for example, p-type dopants, n-type dopants, or a combination thereof) are introduced into the dielectric material, and inner spacers 224 include doped dielectric material(s).

Source/drains 225 include a semiconductor material and may be doped with n-type dopants and/or p-type dopants. When forming a portion of a p-type transistor, source/drains 225 may include silicon germanium or germanium doped with boron, other p-type dopant, or a combination thereof. When forming a portion of an n-type transistor, source/drains 225 may include silicon doped with carbon, phosphorous, arsenic, other n-type dopant, or a combination thereof. Source/drains 225 may include more than one semiconductor layer, where the semiconductor layers include the same or different materials and/or the same or different dopant concentrations. Source/drains 225 may include materials and/or dopants that achieve desired tensile stress and/or compressive stress in channel region C. In some embodiments, source/drains 225 are formed using epitaxial growth processes, and source/drains 225 may be referred to as epitaxial source/drains. In some embodiments, doped regions, such as heavily doped source/drain (HDD) regions, lightly doped source/drain (LDD) regions, other doped regions, or a combination thereof, are disposed in source/drains 225. In some embodiments, doped regions, such as LDD regions, may extend into channel region C. As used herein, source/drain region, source/drain, source/drain feature, etc. may refer to a source of a device, a drain of a device, or a source and/or a drain of multiple devices. In some embodiments, bottom source/drain isolation structures may be formed between substrate 202 and source/drains 225.

Dummy gate 232 extends lengthwise in a direction that is different than (e.g., orthogonal to) the lengthwise direction of semiconductor stack 210. For example, dummy gate 232 extends lengthwise along the y-direction, having a length along the y-direction, a width along the x-direction, and a height along the z-direction. In FIG. 3A, dummy gate 232 is disposed on a top of semiconductor stack 210. In FIG. 3B, dummy gate 232 is disposed over a top and sidewalls of semiconductor stack 210, and dummy gate 232 wraps semiconductor stack 210. Dummy gate 232 may include a dummy gate electrode and a dummy gate dielectric. The dummy gate electrode includes a suitable dummy gate material, such as polysilicon (e.g., a poly gate), and the dummy gate dielectric includes a suitable dielectric material, such as silicon oxide (i.e., a dummy oxide). Dummy gate 232 may include additional layers, such as a hard mask layer (e.g., a nitride mask), other suitable layer, or a combination thereof.

Gate spacers 240 are adjacent to and along sidewalls of dummy gate 232. Gate spacers 240 may include seal spacers, offset spacers, sacrificial spacers, dummy spacers, main spacers, other suitable spacers, or a combination thereof. Gate spacers 240 may have single layer structures or multilayer structures. Gate spacers 240 include a dielectric material, which may include silicon, oxygen, carbon, nitrogen, other suitable constituent, or a combination thereof (e.g., silicon oxide, silicon nitride, silicon oxynitride, silicon carbide, silicon carbonitride, silicon oxycarbide, silicon oxycarbonitride, etc.). For example, gate spacers 240 may include silicon, oxygen, nitrogen, carbon, and hydrogen (i.e., gate spacers 240 may be SiONCH layers).

Dielectric layer 250 is disposed over substrate 202, substrate isolation structure 222, source/drains 225, and gate structure 230. Dielectric layer 250 may have a multilayer structure, such as a contact etch stop layer (CESL) 252 and an interlayer dielectric (ILD) layer 254. ILD layer 254 is formed over CESL 252. ILD layer 254 includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or a combination thereof. In some embodiments, ILD layer 254 includes a dielectric material having a dielectric constant that is less than a dielectric constant of silicon dioxide (e.g., k<3.9). In some embodiments, ILD layer 254 includes a dielectric material having a dielectric constant that is less than about 2.5 (i.e., an extreme low-k dielectric material), such as porous silicon oxide, silicon carbide, carbon-doped oxide (e.g., SiCOH-based material (having, e.g., Si—CH₃ bonds)), or a combination thereof. CESL 252 includes a dielectric material that is different than the dielectric material of ILD layer 254. For example, where ILD layer 254 includes silicon and oxygen (e.g., porous silicon oxide), CESL 252 may include silicon and nitrogen, and CESL 254 may be a silicon nitride layer, a silicon carbonitride layer, or a silicon oxycarbonitride layer.

In some embodiments, the device precursor is received before and/or after forming dielectric layer 250. Forming dielectric layer 250 may include depositing a dielectric material over substrate 202, substrate isolation structure 222, source/drains 225, and gate structure 230 and performing a planarization process, such as a chemical mechanical polishing (CMP), on the dielectric material. The planarization process removes any dielectric material from over gate structure 230. Dummy gate 232 may function as a planarization stop layer, and the planarization process may be performed until reaching dummy gate 232. The planarization process may planarize a top surface of dielectric layer 250 and a top surface of gate structure 230. In some embodiments, dielectric layer 250 is a device-level dielectric layer of a multilayer interconnect (MLI) feature, which electrically connects devices (for example, transistors, resistors, capacitors, inductors, etc.), components of devices (for example, gates and/or source/drains), devices within the MLI feature, components of the MLI feature, or a combination thereof, such that the devices and/or components may operate as specified by design requirements.

Turning to FIG. 1, FIG. 4A, and FIG. 4B, method 100 at block 110 includes removing dummy gate 232 to form a gate opening 255 that exposes semiconductor stack 210. Gate opening 255 has sidewalls formed by gate spacers 240 and a bottom formed by semiconductor stack 210 and/or substrate isolation structure 222. In some embodiments, an etching process selectively removes dummy gate 232 with respect to gate spacers 240, dielectric layer 250, or a combination thereof. For example, the etching process etches dummy gate 232 with no (or negligible) etching of gate spacers 240, substrate isolation structure 222, dielectric layer 250, or a combination thereof. An etchant of the etching process may etch polysilicon (i.e., dummy gate 232) at a higher rate than dielectric materials (i.e., gate spacers 240, substrate isolation structure 222, dielectric layer 250, etc.). The etching process is a dry etch, a wet etch, other suitable etch, or a combination thereof. In some embodiments, a patterned mask layer covers dielectric layer 250 and/or gate spacers 240 but exposes dummy gate 232 during the etching process.

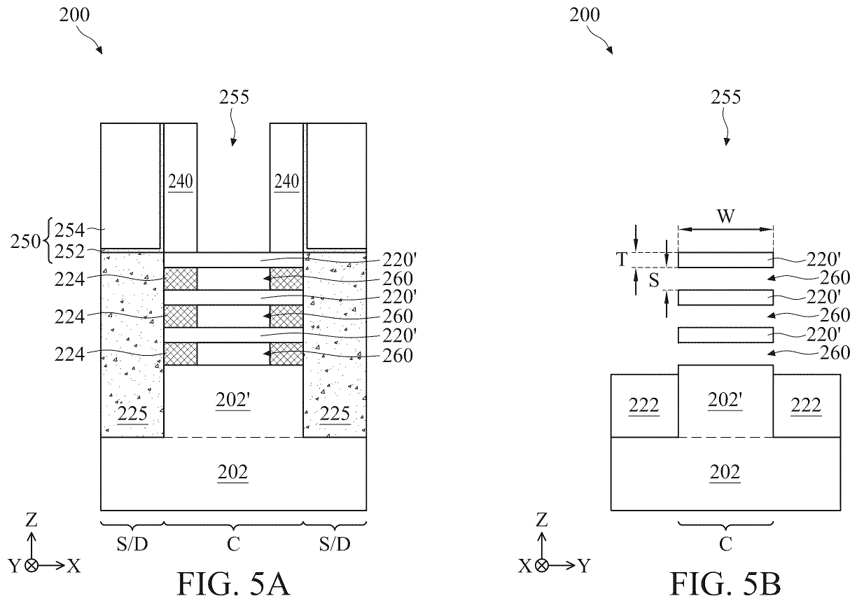

Turning to FIG. 1, FIG. 5A, and FIG. 5B, method 100 at block 115 may include performing a channel release process on the semiconductor stack to form a first channel layer disposed over a second channel layer. For example, semiconductor layers 215 exposed by gate opening 255 are selectively removed to form gaps 260 between semiconductor layers 220 and between semiconductor layers 220 and mesa 202′, thereby suspending semiconductor layers 220 in channel region C. In the depicted embodiment, three suspended semiconductor layers 220 are vertically stacked along the z-direction (i.e., a first semiconductor layer, a second semiconductor layer, and a third semiconductor layer vertically stacked and separated from one another by gaps 260), and suspended semiconductor layers 220 provide three channels through which current may flow between source/drains 225. Suspended semiconductor layers 220 are thus referred to hereafter as channel layers 220′. Channel layers 220′ have a width W along the y-direction, a thickness T along the z-direction, and a spacing S along the z-direction. In some embodiments, width W is about 10 nm to about 60 nm. In some embodiments, thickness T is about 5 nm to about 10 nm. In some embodiments, spacing S is about 5 nm to about 15 nm.

In some embodiments, the channel release process includes an etching process that selectively removes semiconductor layers 215 with respect to semiconductor layers 220, mesa 202′, gate spacers 240, inner spacers 224, substrate isolation structure 222, dielectric layer 250, or a combination thereof. For example, the etching process etches semiconductor layers 215 with no (or negligible) etching of semiconductor layers 220, mesa 202′, gate spacers 240, inner spacers 224, substrate isolation structure 222, dielectric layer 250, or a combination thereof. An etchant of the etching process may etch silicon germanium (i.e., semiconductor layers 215) at a higher rate than silicon (i.e., semiconductor layers 220) and dielectric materials (i.e., gate spacers 240, inner spacers 224, substrate isolation structure 222, dielectric layer 250, etc.). The etching process is a dry etch, a wet etch, other suitable etching process, or a combination thereof. In some embodiments, before performing the etching process, an oxidation process converts semiconductor layers 215 into semiconductor oxide features (e.g., silicon germanium oxide), and the etching process then removes the semiconductor oxide features. In some embodiments, during and/or after removing semiconductor layers 215, an etching process is performed to modify a profile of semiconductor layers 220 to achieve target dimensions and/or target shapes for channel layers 220′, such as cylindrical-shaped channel layers (e.g., nanowires), rectangular-shaped channel layers (e.g., nanobars), sheet-shaped channel layers (e.g., nanosheets), etc.

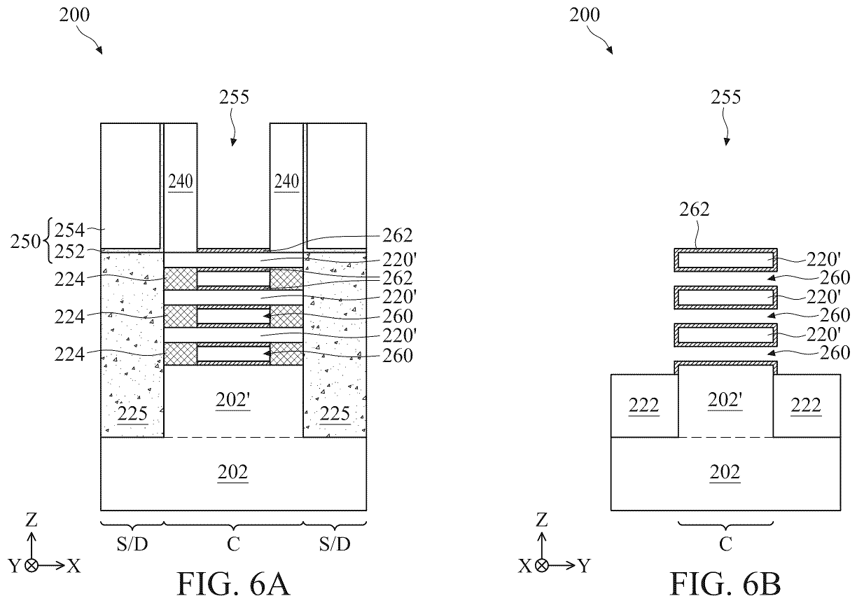

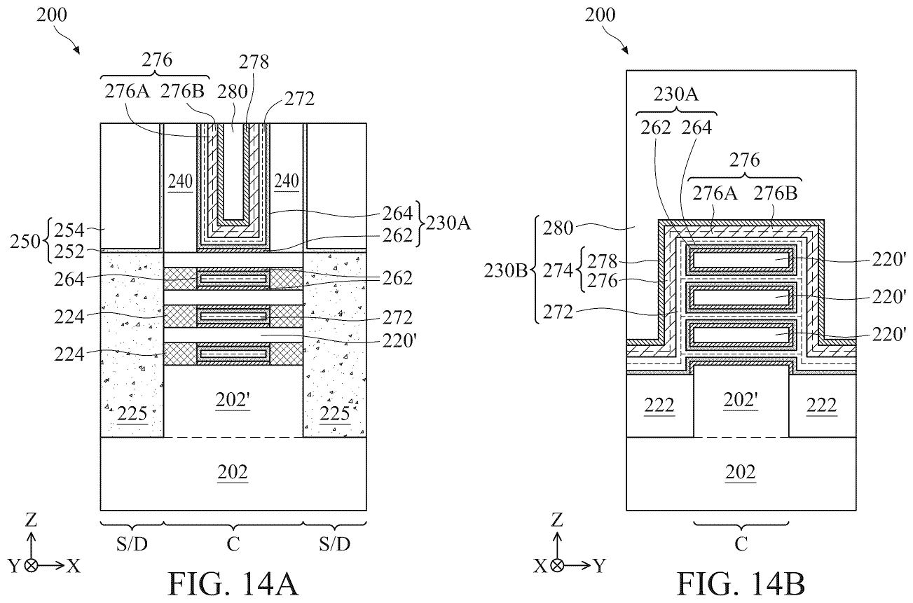

Turning to FIG. 1, FIGS. 6A-14A, and FIGS. 6B-14B, method 100 at block 120 includes forming a gate stack in gate opening 255. The gate stack includes a gate dielectric 230A (e.g., at least one dielectric gate layer) and a gate electrode 230B (e.g., at least one electrically conductive gate layer, such as a work function layer and/or a bulk/fill metal layer). The gate stack fills gate opening 255 and, in the depicted embodiment, air gaps 260 (see FIG. 14A and FIG. 14B). For example, the gate stack is disposed between channel layers 220′ and between channel layers 220′ and mesa 202′. In the X-Z plane (FIG. 14A), the gate stack is disposed between gate spacers 240 and between inner spacers 224. In the Y-Z plane (FIG. 14B), the gate stack at least partially surrounds (e.g., encircles) channel layers 220′. The gate stack may include more or less layers than depicted and described herein. The gate stack and gate spacers 240 may collectively be referred to as gate structure 230.

Referring to FIG. 1A, FIG. 6A, and FIG. 6B, method 100 at block 125 includes forming an interfacial layer 262 in gate opening 255. Interfacial layer 262 partially fills gate opening 255 and partially fills gaps 260 (i.e., spaces) between channel layers 220′. Interfacial layer 262 includes a dielectric material, such as SiO₂, SiGeOₓ, HfSiO, SiON, other dielectric material, or a combination thereof. In some embodiments, interfacial layer 262 forms on semiconductor surfaces (e.g., channel layers 220′ and mesa 202′) but not dielectric surfaces (e.g., inner spacers 224, substrate isolation structure 222, gate spacers 240, and dielectric layer 250), such as depicted. For example, interfacial layer 262 may be formed by an oxidation process, such as thermal oxidation and/or chemical oxidation, where oxygen reacts with semiconductor surfaces to form a semiconductor oxide (i.e., interfacial layer 262) but not dielectric surfaces. In FIG. 6A, interfacial layer 262 covers top surfaces of channel layers 220′, bottom surfaces of channel layers 220′, and a top surface of mesa 202′. In FIG. 6B, interfacial layer 262 surrounds channel layers 220′ and wraps mesa 202′. In some embodiments, interfacial layer 262 is formed by atomic layer deposition (ALD) and/or other suitable method. In some embodiments, interfacial layer 262 has a substantially uniform thickness, such as depicted. In some embodiments, interfacial layer 262 has a thickness of about 5 Å to about 25 Å.

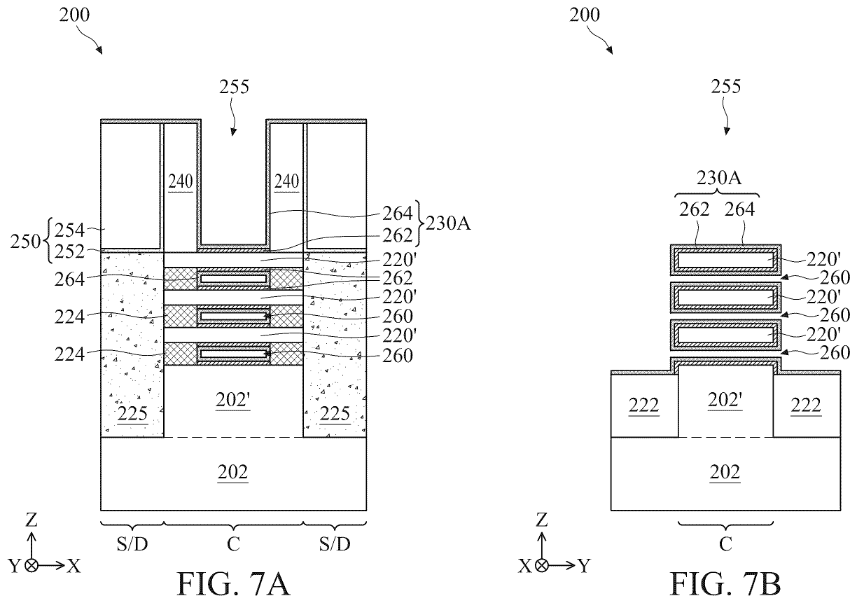

Referring to FIG. 1, FIG. 7A, and FIG. 7B, method 100 at block 130 includes forming a high-k dielectric layer 264 over interfacial layer 262. High-k dielectric layer 264 partially fills gate opening 255 and partially fills gaps 260 (i.e., spaces) between channel layers 220′. High-k dielectric layer 264 may be formed over gate spacers 240, inner spacers 224, substrate isolation structure 222, and dielectric layer 250 (e.g., when formed by a conformal deposition process). High-k dielectric layer 264 includes a high-k dielectric material, such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si_{3P4}, HfO₂—Al₂O₃, other high-k dielectric material, or a combination thereof. High-k dielectric material generally refers to a dielectric material having a dielectric constant that is greater than a dielectric constant of silicon dioxide (k≈3.9). For example, high-k dielectric layer 264 is a hafnium-based oxide (e.g., HfO₂) layer or a zirconium-based oxide (e.g., ZrO₂) layer. In FIG. 7A, high-k dielectric layer 264 has a u-shaped profile in a top portion of gate opening 255 and rectangular-shaped profiles in a bottom portion of gate opening 255 (i.e., in gaps 260). In FIG. 7B, high-k dielectric layer 264 surrounds channel layers 220′ and wraps mesa 202′. High-k dielectric layer 264 is formed by ALD, CVD, physical vapor deposition (PVD), other suitable process, or a combination thereof. A thickness of high-k dielectric layer 264 is greater than a thickness of interfacial layer 262. In some embodiments, a thickness of high-k dielectric layer 264 is about 10 Å to about 50 Å. In some embodiments, high-k dielectric layer 264 has a substantially uniform thickness, such as depicted.

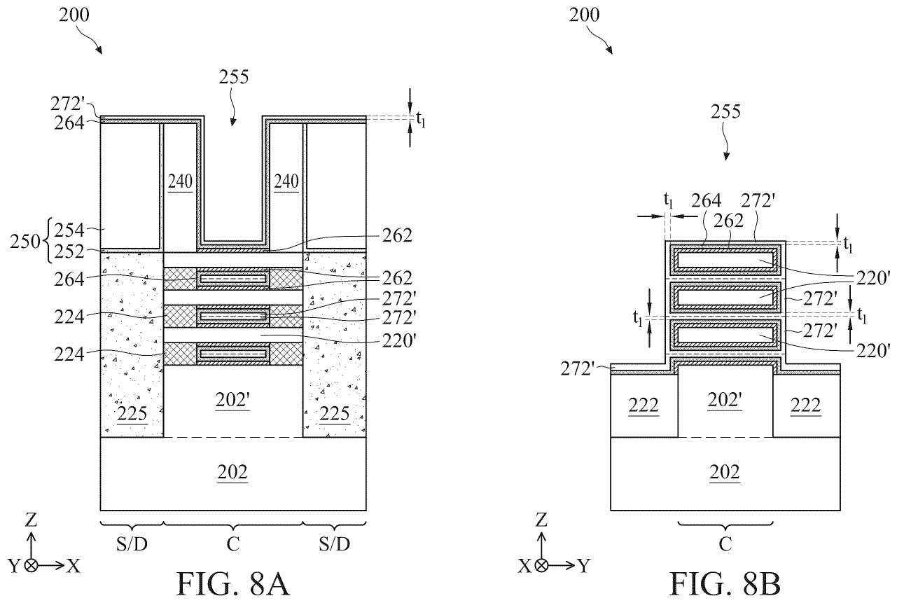

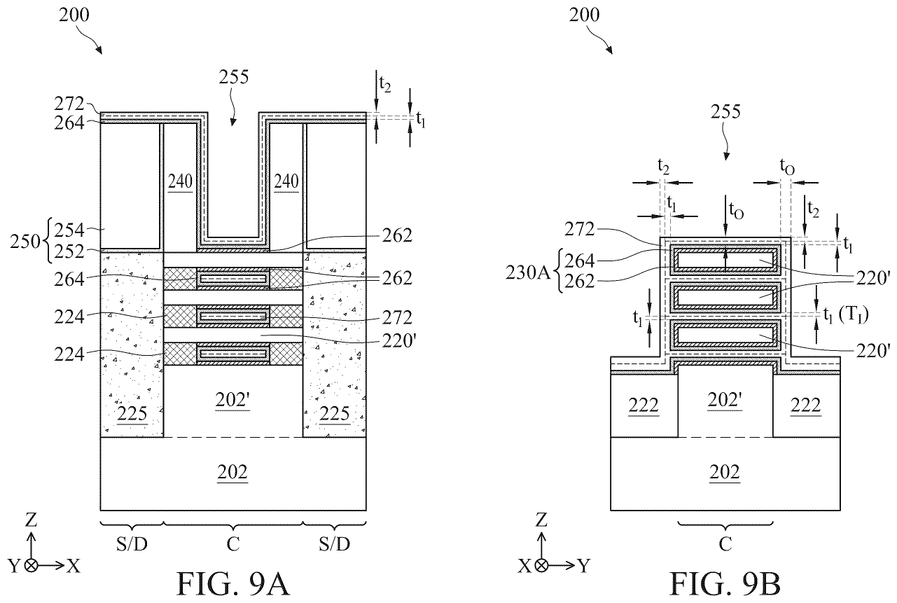

Referring to FIG. 1, FIG. 8A, FIG. 8B, FIG. 9A, and FIG. 9B, method 100 at block 135 includes forming a work function layer 272 over high-k dielectric layer 264. Work function layer 272 partially fills gate opening 255 and fills remainders of gaps 260 (i.e., spaces) between channel layers 220′. Gaps 260 between channel layers 220′ and between bottommost channel layer 220′ and mesa 202′ are thus filled by work function layer 272 and gate dielectric 230A (e.g., high-k dielectric layer 264 and interfacial layer 262), in the depicted embodiment. In FIG. 9A, work function layer 272 has a u-shaped profile in a top portion of gate opening 255 and rectangular-shaped profiles in a bottom portion of gate opening 255 (i.e., in gaps 260). In FIG. 9B, work function layer 272 surrounds channel layers 220′ and wraps mesa 202′.

Work function layer 272 is formed by ALD, CVD, PVD, other suitable process, or a combination thereof. In the depicted embodiment, work function layer 272 is formed by depositing work function material in gate opening 255 (including gaps 260) to form work function layers 272′ around channel layers 220′ that merge together and fill remainders of gaps 260 (FIG. 8A and FIG. 8B) and continuing to deposit work function material in gate opening 255 to increase thicknesses of outer regions of work function layers 272′ (i.e., those portions that are not between channel layers 220′) and increase merger of work function layers 272′ (FIG. 9A and FIG. 9B), such that work function layers 272′ around channel layers 220′ combine to form work function layer 272. In FIG. 8A and FIG. 8B, work function layers 272′ have a thickness t1 when merged between channel layers 220′ and filling remainders of gaps 260. In some embodiments, thickness t1 is about 15 Å to about 25 Å. In some embodiments, thickness t1 is about ½ of spacing S between channel layers 220′. In FIG. 9A and FIG. 9B, a thickness of outer regions of work function layers 272′ is increased by a thickness t2. In some embodiments, thickness t2 is about 5 Å to about 15 Å. In some embodiments, thickness t2 is less than thickness t1. In some embodiments, thickness t2 is greater than thickness t1. In some embodiments, thickness t2 is about equal to thickness t1. In some embodiments, work function layers 272′ are formed by a conformal deposition process, and work function layers 272′ have substantially uniform thicknesses. For example, thickness t1 of each of work function layers 272′ may be the same along a top, a bottom, and both sidewalls of a respective channel layer 220′.

A thickness of outer regions of work function layer 272 (i.e., those portions along sidewalls of channel layers 220′ and along a top of top channel layer 220′) is thus greater than a thickness of inner regions of work function layer 272 (i.e., those portions between channel layers 220′ and between bottom channel layer 220′ and mesa 202′). For example, a portion of work function layer 272 around top channel layer 220′ has an outer thickness T_{O} and an inner thickness T_{I}, and outer thickness T_{O} is greater than inner thickness T_{I}. The portion of work function layer 272 has outer thickness T_{O} along a top and sidewalls of top channel layer 220′, and the portion of work function layer 272 has inner thickness T_{I} along a bottom of top channel layer 220′. In the depicted embodiment, outer thickness T_{O} is a sum of thickness t1 and thickness t2, and inner thickness T_{I} is thickness t1. In some embodiments, outer thickness T_{O} is about 20 Å to about 40 Å. In some embodiments, inner thickness T_{I} is about 15 Å to about 25 Å. In some embodiments, inner thickness T_{I} is about ½ of spacing S between channel layers 220′. Further, a portion of work function layer 220′ around middle channel layer 220′ may have outer thickness T_{O} along sidewalls of middle channel layer 220′ and inner thickness T_{I} along a top and a bottom of middle channel layer 220′, and a portion of work function layer 220′ around bottom channel layer 220′ may have outer thickness T_{O} along sidewalls of bottom channel layer 220′ and inner thickness T_{I} along a top and a bottom of bottom channel layer 220′.

Work function layer 272 is an electrically conductive layer tuned to have a desired work function. Work function layer 272 may be an n-type work function metal (N-WFM) layer, a p-type work function metal (P-WFM) layer, or a combination thereof. An N-WFM layer (also referred to as an n-metal layer) includes an n-type work function material, which generally refers to an electrically conductive material tuned to have an n-type work function, and a p-WFM layer (also referred to as a p-metal layer) includes a p-type work function material, which generally refers to an electrically conductive material tuned to have a p-type work function. The n-type work function material may include a metal with a sufficiently low effective work function, such as aluminum, titanium, tantalum, zirconium, other n-metal, alloys thereof, or a combination thereof. In some embodiments, the N-WFM layer is a titanium aluminum layer, a titanium aluminum carbide layer, a tantalum carbide layer, a tantalum carbide nitride layer, or a tantalum silicon nitride. The p-type work function material may include a metal with a sufficiently high effective work function, such as titanium, tantalum, ruthenium, molybdenum, tungsten, platinum, other p-metal, alloys thereof, or a combination thereof. In some embodiments, the P-WFM layer is a titanium nitride layer, a titanium carbide layer, a titanium silicon nitride layer, a tantalum nitride layer, a tungsten carbonitride layer, or a molybdenum layer. In some embodiments, the work function layer has a multilayer structure, such as more than one N-WFM layer, more than one P-WFM layer, or an N-WFM layer(s) and a P-WFM layer(s). In some embodiments, work function layer 272 is tuned to have an n-type work function or a p-type work function depending on a type of transistor to which it belongs. For example, when device 200 is configured as an n-type transistor, work function layer 272 may be an N-WFM layer, and when device 200 is configured as a p-type transistor, work function layer 272 may be a P-WFM layer.

In the depicted embodiment, work function layer 272 is an N-WFM layer, such as a titanium aluminum carbide layer (TiAlC) layer or a titanium aluminide (TiAl) layer, formed by ALD. For example, work function layer 272 includes titanium, aluminum, and carbon. In another example, work function layer 272 includes titanium and aluminum. An aluminum concentration/content in work function layer 272 depends on a thickness of work function layer 272. For example, the aluminum content in work function layer 272 is inversely proportional to the thickness of work function layer 272, and to maintain a desired threshold voltage, the aluminum content in work function layer 272 may be increased or decreased depending on the thickness of work function layer 272. Accordingly, if a desired threshold voltage corresponds with a work function layer having a given thickness and a given aluminum content and work function layer 272 is configured with a thickness that is less than the given thickness, an aluminum content may be configured greater than the given aluminum content to maintain the desired threshold voltage (i.e., aluminum content increases as thickness decreases). Further, if work function layer 272 is configured with a thickness that is greater than the given thickness, an aluminum content of work function layer 272 may be configured less than the given aluminum content to maintain the desired threshold voltage (i.e., aluminum content decreases as thickness increases). In the depicted embodiment, since a thickness of work function layer 272 is increased to fill remainders of gaps 260 (i.e., work function layer 272 is thicker), work function layer 272 may be configured with a lower aluminum content to obtain a given threshold voltage. For example, work function layer 272 having a total thickness (e.g., t₁+t₂) that is less than about 20 Å (e.g., 15 Å to about 20 Å), which will not fill remainders of gaps 260 between channel layers 220′, may have an aluminum content that is greater than 33 atomic percent (at %) (e.g., about 40 at %) to obtain a desired threshold voltage, while in the depicted embodiment, thicker work function layer 272 having a total thickness that is greater than 20 Å (e.g., about 25 Å to about 35 Å), which will fill remainders of gaps 260, may have a lower aluminum content, such as an aluminum content of about 25 at % to about 33 at % to obtain the same desired threshold voltage. Thicker work function layer 272 having aluminum content that is less than about 25 at % may not maintain the desired threshold voltage, while thicker work function layer 272 having aluminum content that is greater than about 33 at % may undesirably increase gate resistance. Configuring work function layer 272 with a lower aluminum content (e.g., about 25 at % to about 33 at %) lowers gate resistance, particularly gate resistance associated with inner portions of the gate stack, such as those portions that fill gaps 260 between channel layers 220′ and/or gap 260 between channel layer 220′ and mesa 202′.

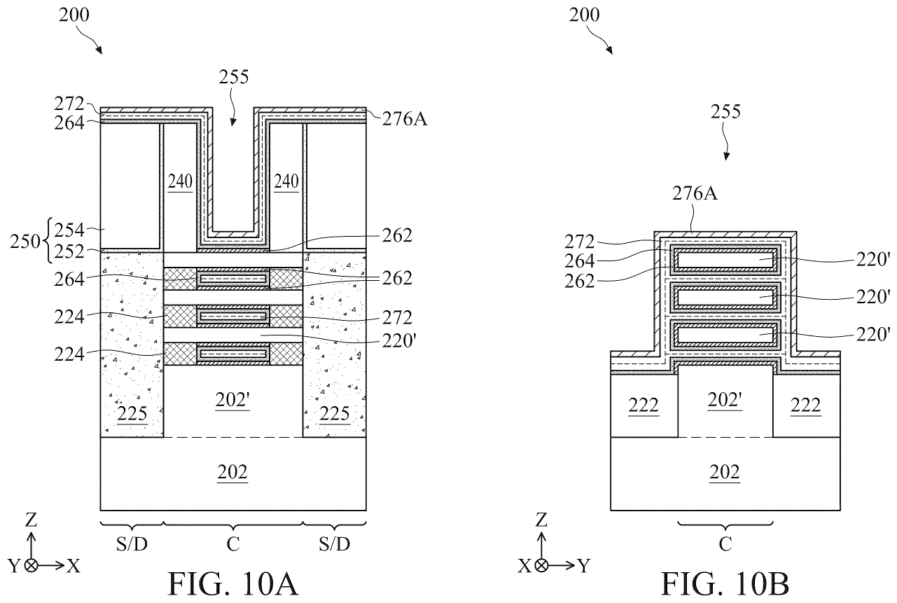

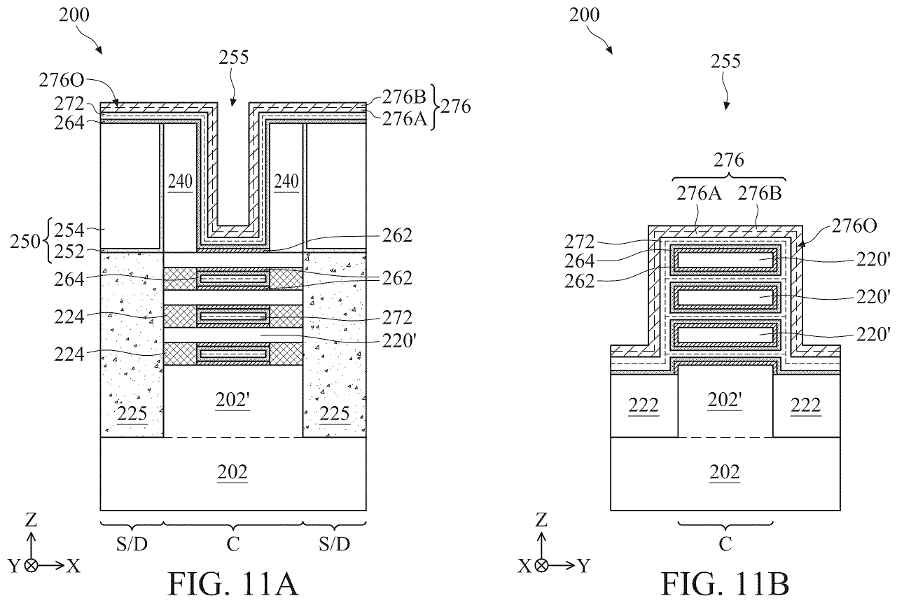

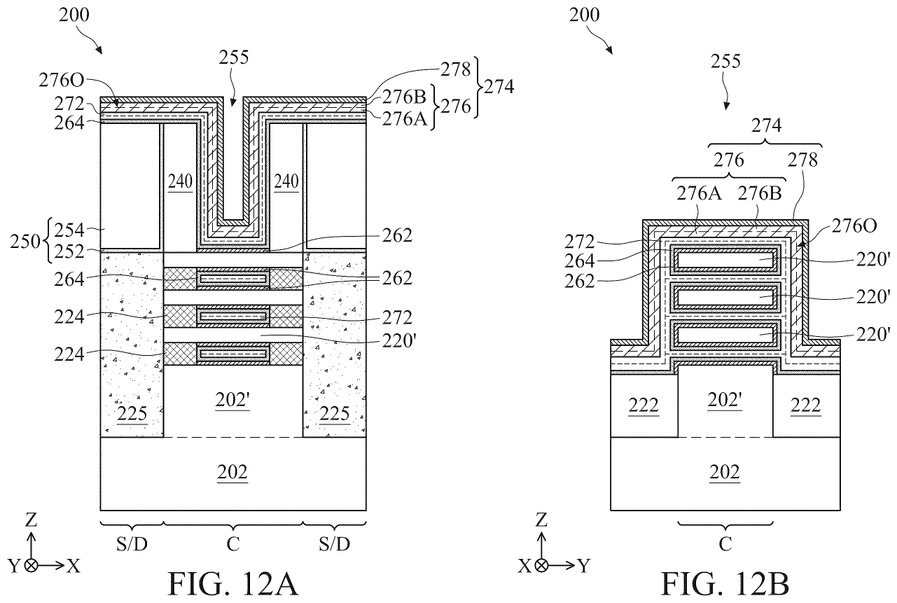

Referring to FIG. 1, FIGS. 10A-12A, and FIGS. 10B-12B, method 100 at block 140 includes forming a cap 274 over work function layer 272. In FIG. 12A and FIG. 12B, cap 274 includes a capping layer 276 and a capping layer 278, and a composition of capping layer 276 is different than a composition of capping layer 278. For example, capping layer 276 is a metal-comprising layer, such as a metal nitride layer, and capping layer 278 is a semiconductor-comprising layer, such as a silicon layer. In some embodiments, block 140 includes forming a metal nitride layer (e.g., capping layer 276) over work function layer 272 (see FIG. 10A, FIG. 10B, FIG. 11A, and FIG. 11B) and forming a silicon-comprising layer (e.g., capping layer 278) over the metal nitride layer (see FIG. 12A and FIG. 12B). In some embodiments, forming capping layer 276 includes forming a first portion of capping layer 276 (e.g., a capping sublayer 276A thereof) over work function layer 272 (FIG. 10A and FIG. 10B) and, after breaking vacuum, forming a second portion of capping layer 276 (e.g., a capping sublayer 276B thereof) (FIG. 11A and FIG. 11B). In the depicted embodiment, since capping layer 276 is a metal nitride layer, capping sublayer 276A and capping sublayer 276B are metal nitride sublayers. In some embodiments, capping sublayer 276 has more than two sublayers, where vacuum may be broken after forming each sublayer or vacuum may be broken after forming some sublayers, but not after forming other sublayers. In some embodiments, capping layer 278 has a multilayer structure. In some embodiments, cap 274 has more than two capping layers.

Referring to FIG. 10A, FIG. 10B, FIG. 11A, and FIG. 11B, capping sublayer 276A is formed over work function layer 272 and partially fills the top portion of gate opening 255 (FIG. 10A, FIG. 10B), and capping sublayer 276B is formed over capping sublayer 276A and partially fills the top portion of gate opening 255 (FIG. 11A, FIG. 11B). Since work function layer 272 fills a remainder of the bottom portion of gate opening 255 (i.e., gaps 260), capping sublayer 276A and capping sublayer 276B are not formed in spaces between neighboring channel layers 220′. Capping sublayer 276A and capping sublayer 276B are formed by ALD, CVD, PVD, other suitable process, or a combination thereof. In FIG. 10A and FIG. 11A, capping sublayer 276A and capping sublayer 276B have u-shaped profiles. In FIG. 10B and FIG. 11B, capping sublayer 276A and capping sublayer 276B wrap channel layers 220′.

As noted, capping sublayer 276A and capping sublayer 276B are metal nitride layers, which may include TiN, TiSiN, TaSiN, TaN, TaCN, WN, WCN, other metal nitride, or a combination thereof. In some embodiments, capping sublayer 276A and capping sublayer 276B include a same metal nitride material. For example, capping sublayer 276A and capping sublayer 276B include titanium and nitrogen, and capping sublayer 276A and capping sublayer 276B are TiN sublayers. In some embodiments, capping sublayer 276A and capping sublayer 276B include different metal nitride materials. A thickness of capping sublayer 276A may be greater than a thickness of capping sublayer 276B. In some embodiments, a thickness of capping sublayer 276A is about 5 Å to about 15 Å. In some embodiments, a thickness of capping sublayer 276B is about 2 Å to about 8 Å. In some embodiments, a total thickness of capping layer 276 (e.g., a sum of a thickness of capping sublayer 276A and a thickness of capping sublayer 276B) is about 5 Å to about 25 Å. In some embodiments, a thickness of capping sublayer 276A is less than a thickness of capping sublayer 276B. In some embodiments, a thickness of capping sublayer 276A is the same as a thickness of capping sublayer 276B.

Capping sublayer 276B and capping sublayer 276A are formed “ex-situ,” which generally refers to breaking vacuum between processes. For example, device 200 is contained in a vacuum-conditioned environment when forming capping sublayer 276A and forming capping sublayer 276B, but device 200 does not remain under vacuum conditions (i.e., device 200 may be exposed to oxygen) between forming capping sublayer 276A and forming capping sublayer 276B. In other words, vacuum is broken between forming capping sublayer 276A and forming capping sublayer 276B, such that device 200 is exposed to air (e.g., atmospheric oxygen) between these process steps. In some embodiments, capping sublayer 276A and capping sublayer 276B are formed in a same process chamber and vacuum is broken between forming capping sublayer 276A and forming capping sublayer 276B. In some embodiments, capping sublayer 276A and capping sublayer 276B are formed in different process chambers of a semiconductor process tool and/or a semiconductor process system and vacuum is broken when transferring device 200 from a process chamber for forming capping sublayer 276A to a process chamber for forming capping sublayer 276B. In some embodiments, capping sublayer 276A and capping sublayer 276B are formed in different semiconductor process tools and/or different semiconductor process systems and vacuum is broken when transferring device 200 between the semiconductor process tools and/or semiconductor process systems.

Because vacuum is broken when forming capping layer 276, capping layer 276 is referred to as an ex-situ capping layer, and cap 274 may be referred to as an ex-situ cap. In some embodiments, breaking vacuum exposes capping sublayer 276A to an oxygen ambient before forming capping sublayer 276B. For example, when vacuum is broken (i.e., device 200 is no longer in a vacuum-conditioned environment), capping sublayer 276A is exposed to air (e.g., atmospheric oxygen), and capping sublayer 276A may adsorb oxygen from the oxygen ambient, which may bond with metal and thus provide capping sublayer 276A with metal-oxygen bonds. As capping sublayer 276A adsorbs oxygen, an exposed surface of capping sublayer 276A may be converted to a thin metal oxide layer and/or a thin metal oxynitride layer, which is depicted as oxidized surface 2760 (also referred to as an oxidized layer 2760). Oxidized layer 2760 may include metal-oxygen bonds, metal-nitrogen bonds, metal-oxygen-nitrogen bonds, or a combination thereof. In some embodiments, a thickness of oxidized layer 2760 of capping sublayer 276A is about 0.1 nm to about 0.2 nm. In embodiments where capping sublayer 276A includes metal-oxygen bonds before vacuum is broken, such as where capping sublayer 276A includes oxygen and/or where oxygen has diffused into capping sublayer 276A during processing of device 200, metal-oxygen bonds of capping sublayer 276A may increase as capping sublayer 276A adsorbs oxygen from the oxygen ambient. Forming and/or increasing metal-oxygen bonds in capping sublayer 276A may reduce and/or repair oxygen vacancies therein, which may mitigate oxygen diffusion from cap 274 and/or subsequently formed layers into work function layer 272 and/or gate dielectric 230A during fabrication of device 200, thereby reducing unintended oxidation and minimizing threshold voltage variations and/or other device performance changes (e.g., reductions in speed and/or mobility) caused by such oxidation. Further, reducing and/or repairing the oxygen vacancies may reduce gate resistance. In the depicted embodiment, where capping sublayer 276A is a TiN sublayer, the TiN sublayer may adsorb oxygen from the oxygen ambient, which forms and/or increases Ti—O bonds of the TiN sublayer. In such embodiments, oxidized layer 2760 and/or capping sublayer 276A may include Ti—N bonds, Ti—O bonds, Ti—O—N bonds, or a combination thereof.

Referring to FIG. 12A and FIG. 12B, capping layer 278 is formed over capping layer 276 (e.g., over capping sublayer 276B thereof). Capping layer 278 partially fills the top portion of gate opening 255. Since work function layer 272 fills a remainder of the bottom portion of gate opening 255 (i.e., gaps 260), capping layer 278 is not formed in spaces between neighboring channel layers 220′. In FIG. 12A, capping layer 278 has a u-shaped profile in the top portion of gate opening 255. In FIG. 12B, capping layer 278 wraps channel layers 220′.

Capping layer 278 includes a material having strong oxygen affinity, which may prevent oxygen diffusion into work function layer 272 and mitigate threshold voltage shifting that may be caused by work function metal oxidation. For example, capping layer 278 is a silicon-comprising layer, which may include silicon, polysilicon, amorphous silicon, or a combination thereof. In some embodiments, a thickness of capping layer 278 is about 10 Å to about 20 Å. In the depicted embodiment, a thickness of capping layer 278 is less than a thickness of capping layer 276. In some embodiments, a thickness of capping layer 278 is greater than a thickness of capping layer 276. In some embodiments, a thickness of capping layer 278 is the same as a thickness of capping layer 276. Capping layer 278 is formed by ALD, CVD, PVD, other suitable process, or a combination thereof. In some embodiments, capping layer 278 is formed ex-situ (e.g., vacuum is broken between forming capping sublayer 276B and capping layer 278). In some embodiments, capping layer 278 is formed in-situ (e.g., vacuum is not broken between forming capping sublayer 276B and capping layer 278).

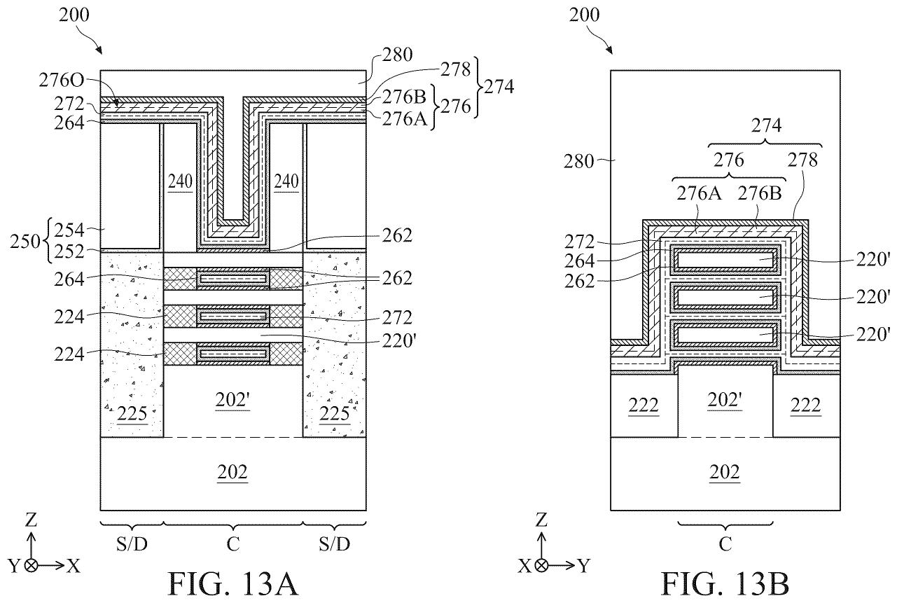

Referring to FIG. 1, FIG. 13A, FIG. 13B, FIG. 14A, and FIG. 14B, method 100 at block 145 includes forming a bulk (fill) layer 280 over cap 274. Bulk/fill layer 280 fills a remainder of gate opening 255. In FIG. 14A, bulk layer 280 has a u-shaped profile in the top portion of gate opening 255. In FIG. 14B, bulk layer 280 wraps channel layers 220′. Since work function layer 272 fills a remainder of the bottom portion of gate opening 255 (i.e., gaps 260), bulk/fill layer 280 is not formed in spaces between neighboring channel layers 220′.

Bulk/fill layer 280 includes an electrically conductive material, such as Al, W, Cu, Ti, Ta, polysilicon, other suitable metal(s) and/or alloys thereof, or a combination thereof. Referring to FIG. 13A and FIG. 13B, the electrically conductive material is deposited (e.g., by ALD, CVD, PVD, other suitable process, or a combination thereof) over dielectric layer 250 and fills gate opening 255. In some embodiments, bulk layer 280 is a tungsten layer formed by PVD or CVD. In some embodiments, bulk layer 280 is a fluorine-free tungsten (FFW) layer. In some embodiments, bulk layer 280 is formed ex-situ (e.g., vacuum is broken between forming capping layer 278 and bulk layer 280). In some embodiments, bulk layer 280 is formed in-situ (e.g., vacuum is not broken between forming capping layer 278 and bulk layer 280).

In some embodiments, bulk layer 280 has a multilayer structure, such as a glue layer and a metal fill layer, such as a tungsten layer). The glue layer may include a material that promotes adhesion between adjacent layers, such as between work function layer 272/cap 274 and the subsequently formed metal fill layer, and/or that prevents or eliminates diffusion and/or reaction of constituents between adjacent layers. For example, the glue layer may include metal and nitrogen, such as TiN, TaN, W₂N, TiSiN, TaSiN, other suitable metal nitride material, or a combination thereof. The glue may be formed ex-situ (e.g., vacuum is broken between forming capping layer 278 and the glue layer) or in-situ (e.g., vacuum is not broken between forming capping layer 278 and the glue layer). The metal fill layer may be formed ex-situ (e.g., vacuum is broken between forming the glue layer and the metal fill layer) or in-situ (e.g., vacuum is not broken between forming the glue layer and the metal fill layer).

Referring to FIG. 14A and FIG. 14B, a planarization process is performed to remove excess gate materials, such as those disposed over dielectric layer 250. For example, a CMP process removes portions of bulk layer 280, cap 274 (e.g., capping layer 276 and capping layer 278), work function layer 272, and high-k dielectric layer 264 that are disposed over dielectric layer 250. The CMP process may be performed until reaching and/or exposing a top surface of dielectric layer 250. In some embodiments, the CMP process may continue to reduce a thickness of dielectric layer 250, and correspondingly, a height of gate structure 230 (e.g., of gate stack thereof). In the depicted embodiment, a top of gate structure 230 is substantially planar with a top of dielectric layer 250 after the planarization process, and remainders of the gate materials, which fill gate opening 255, form the gate stack of gate structure 230.

Method 100 thus provides device 200 with a gate stack having gate dielectric 230A (e.g., interfacial layer 262 and high-k dielectric layer 264) and gate electrode 230B (e.g., bulk/fill layer 280, cap 274 (e.g., capping layer 276 and capping layer 278), and work function layer 272). Since gate dielectric layer 230A includes high-k dielectric layer 264, the gate stack may be referred to as a high-k/metal gate. As noted above, introducing a vacuum break when forming capping layer 276 (and thus introducing oxygen into the gate stack) may improve performance of a device by reducing oxidation, minimizing threshold voltage variations, increasing its speed and/or mobility, or a combination thereof. However, it has been observed that, when capping layer 276 is incorporated and/or formed in inner regions of the gate stack (i.e., those regions between neighboring channel layers 220′ and/or between bottom channel layer 220′ and mesa 202′), an amount of oxygen in outer regions of the gate stack (e.g., those regions not between neighboring channel layers 220′ and/or between bottom channel layer 220′ and mesa 202′) is greater than an amount of oxygen in inner regions of the gate stack, which causes undesirable threshold voltage variations. The disclosed gate stack reduces an oxygen difference between the inner regions and the outer regions by filling spaces between neighboring channel layers 220′ and/or between bottom channel layer 220′ and mesa 202′ with work function layer 272, such that capping layer 276 is not incorporated and/or formed in the inner regions of the gate stack.

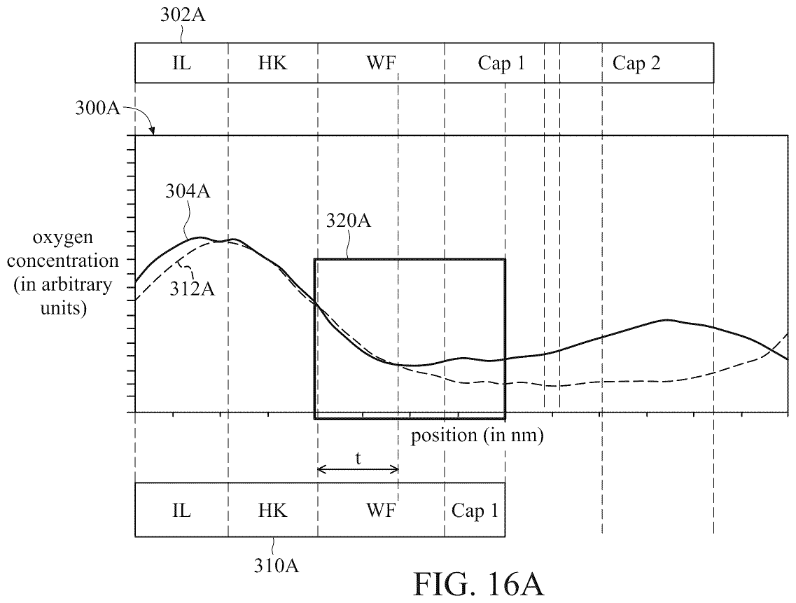

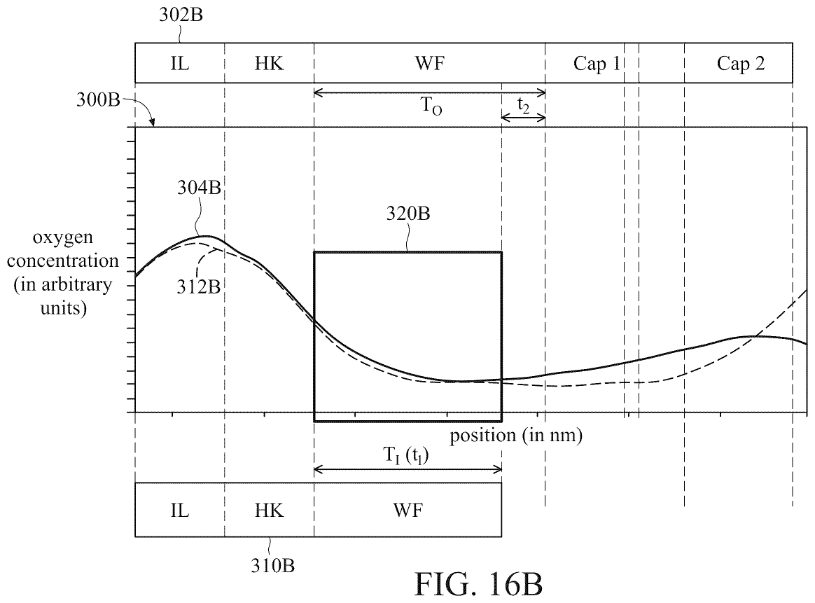

Referring to FIG. 16A and FIG. 16B, FIG. 16A is an energy-dispersive x-ray spectroscopy (EDX) map 300A of oxygen in an inner region and an outer region of a gate stack having a cap (e.g., a portion of capping layer 276) in the inner region, according to various aspects of the present disclosure, and FIG. 16B is an EDX map 300B of oxygen in an inner region and an outer region of a gate stack without the cap in the inner region, such as the gate stack of device 200, according to various aspects of the present disclosure. Each of EDX map 300A and EDX map 300B has a y-axis representing an oxygen concentration (in arbitrary units) and an x-axis representing a position within a gate stack (in nanometers (nm)). EDX map 300A and EDX map 300B provide outer oxygen profiles taken from outer film stacks of their respective gate stacks, such as an outer film stack 302A and an outer film stack 302B, and the outer oxygen profiles are represented by a curve 304A and a curve 304B, respectively. The outer film stacks may include an interfacial (IL) layer (e.g., interfacial layer 262), a high-k dielectric (HK) layer (e.g., high-k dielectric layer 264), a work function (WF) layer (e.g., work function layer 272), and a capping layer formed of a cap 1 (e.g., capping layer 276) and a cap 2 (e.g., capping layer 278). Outer film stack 302A and outer film stack 302B may be portions of a gate stack that are disposed along sidewalls of a respective channel layer or disposed over a top of a respective topmost channel layer. Outer film stack 302A is different than outer film stack 302B. For example, a thickness of the WF layer of outer film stack 302A is less than a thickness of the WF layer of outer film stack 302B, and a total thickness of the cap (e.g., cap 1 and cap 2) of outer film stack 302A is greater than a thickness of the cap of outer film stack 302B.

EDX map 300A and EDX map 300B further provide inner oxygen profiles taken from inner film stacks of their respective gate stacks, such as an inner film stack 310A and an inner film stack 310B, and the inner oxygen profiles are represented by a curve 312A and a curve 312B, respectively. The inner film stacks may include the IL layer (e.g., interfacial layer 262) and the HK layer (e.g., high-k dielectric layer 264). Inner film stack 310A is different than inner film stack 310B. For example, inner film stack 310A further includes both the WF layer (e.g., work function layer 272) and a portion of the capping layer, such as a portion of the cap 1 (e.g., capping layer 276), while inner film stack 310B further includes the WF layer (e.g., work function layer 272), but not a portion of the capping layer. Inner film stack 310A and inner film stack 310B may be portions of a gate stack that are between neighboring channel layers, such as between a respective topmost channel layer and a respective middle channel layer. The gate stack corresponding with EDX map 300B thus does not include the cap between neighboring channel layers and may be configured like the gate stack of device 200 described herein.

For the gate stack corresponding with EDX map 300A, a region 320A of EDX map 300A corresponds with a gate electrode portion of the gate stack that forms a part of both outer film stack 302A and inner film stack 310A. As shown by curve 304A and curve 312A, in region 320A, an outer oxygen concentration and an inner oxygen concentration are substantially similar (i.e., a difference therebetween is relatively small) until the WF layer reaches a thickness t, at which point the outer oxygen concentration begins increasing and the inner oxygen concentration begins decreasing. Accordingly, an oxygen content of an upper portion of the WF layer in outer film stack 302A is greater than an oxygen content of an upper portion of the WF layer in inner film stack 310A, and an oxygen content of a lower portion of the cap 1 in outer film stack 302A is greater than an oxygen content of a lower portion of the cap 1 in inner film stack 310A. In some instances, a gate stack configured as the gate stack corresponding with EDX map 300A has been observed to have a ratio of oxygen in outer regions to oxygen in inner regions that is about 1.3 to about 1.5 (e.g., about 1.4). Such oxygen differences and/or oxygen ratios may undesirably increase threshold voltage, for example, to about 70 millivolts (mV) to about 80 mV.

In contrast, as shown by curve 304B and curve 312B in a region 320B of EDX map 300B, which corresponds with a gate electrode portion of the gate stack that forms a part of both outer film stack 302B and inner film stack 310B, an outer oxygen concentration and an inner oxygen concentration are substantially similar (i.e., a difference therebetween is relatively small) for an entire thickness of region 320B. Accordingly, though an oxygen content of outer film stack 302B may be slightly greater than an oxygen content of inner film stack 310B, a difference therebetween is significantly less than that provided when both the cap 1 and the WF layer form a remainder of an inner film stack, such as inner film stack 310A. A gate stack configured as the gate stack corresponding with EDX map 300B, such as disclosed herein, may thus reduce a ratio of oxygen in outer regions to oxygen in inner regions of a gate stack. In some instances, a gate stack configured as the gate stack corresponding with EDX map 300B, such as the gate stack of device 200, has a ratio of oxygen in outer regions to oxygen in inner regions that is about 1.0 to about 1.25 (e.g., about 1.1). Such oxygen differences and/or oxygen ratios may reduce threshold voltage, for example, to about 40 mV to about 50 mV, which may improve performance.

Further, increasing a thickness of the WF layer in outer film stack 302B (e.g., T_{O}) relative to a thickness of WF layer in inner film stack 310B (e.g., T_{I}) may reduce migration and/or diffusion of oxygen into inner film stack 310B. For example, the WF layer of the gate stack corresponding with EDX map 300B is configured with a sacrificial/buffer portion (i.e., a portion of the WF layer that is deposited/grown after filling spacings between neighboring channel layers (e.g., having thickness t₂)), which may compensate for oxygen diffusion and/or migration into the WF layer that occurs when forming the cap 1 and/or other subsequently deposited gate stack layers. In other words, outer film stack 302B is configured to account for oxygen diffusion into the WF layer and provide a greater distance between the cap 1 and portion of the WF layer belonging to inner film stack 310B. Accordingly, as shown by curve 304B in a region of EDX map 300B that corresponds with the sacrificial portion of the WF layer, an oxygen content of the sacrificial portion of the WF layer begins to increase, and the oxygen content of the WF layer of the outer film stack 302B decreases from a first oxygen concentration to a second oxygen concentration and then increases from second oxygen concentration to a third oxygen concentration that is less than the first oxygen concentration.

Referring again to FIG. 14A and FIG. 14B, the disclosed gate stack having an inner film stack formed from a gate dielectric and a low aluminum content work function layer (e.g., less than about 33 at %) and methods of fabrication thereof provide numerous advantages. When compared to a device having a gate stack configured with an inner film stack having a gate dielectric, a high aluminum content work function layer (e.g., greater than 33 at % to compensate for it being thinner), and an ex-situ cap (e.g., a portion of a metal nitride layer), the gate stack of device 200, which omits a cap from its inner film stack, may reduce gate induced leakage current (I_{gi}) by about 0.5× to about 0.8×, subthreshold leakage current (I_{sb}), overall gate resistance (R_{g}) (in some instances, by as much as 40%), improve time-dependent dielectric breakdown (TDDB), or a combination thereof. Such improvements may be achieved while maintaining and/or reducing desired threshold voltages and/or reducing threshold voltage variations between an inner film stack and an outer film stack of a gate stack. Different embodiments may have different advantages, and no particular advantage is required of any embodiment.

Referring to FIG. 15A and FIG. 15B, in some embodiments, when depositing work function material 272′ as described with reference to FIG. 8A and FIG. 8B, portions of work function material 272′ along sidewalls of channel layers 220′ may merge together at ends of gaps 260 before completely filling middles of gaps 260, such that air gaps 290 (also referred to as voids) may form within work function layer 272 in spaces between channel layers 220′. In such embodiments, a respective air gap 290 is formed between a portion of work function material 272′ that forms along a bottom of a first one of channel layers 220′ and a portion of work function material 272′ that forms along a top of a second one of channel layers 220′. Air gaps 290 may have various shape profiles, and in some embodiments, more than one air gap may be formed in a space between neighboring channel layers 220′. In the depicted embodiment, lengths of air gaps 290 are greater than or equal to widths of channel layers 220′. In some embodiments, lengths of air gaps 290 are less than widths of channel layers 220′.

In some embodiments, processing can further include etching back gate electrode 230B and/or gate dielectric 230A and forming a hard mask, such as a self-aligned cap (SAC), over the etched-back gate electrode 230B and/or gate dielectric 230A. The hard mask can include a dielectric material, such as silicon oxide, silicon nitride, silicon carbide, silicon carbonitride, silicon oxynitride, silicon oxycarbonitride, aluminum oxide, aluminum nitride, aluminum oxynitride, zirconium oxide, zirconium nitride, zirconium aluminum oxide, hafnium oxide, other suitable dielectric material, or a combination thereof.

In some embodiments, processing can further include forming interconnects, such as gate contacts and/or source/drain contacts. In some embodiments, forming source/drain contacts includes forming a source/drain contact opening in dielectric layer 250 that exposes an epitaxial source/drain (e.g., epitaxial source/drain 225) and forming at least one electrically conductive layer (e.g., metal) in the source/drain contact openings. In some embodiments, the source/drain contact openings are formed by forming a patterned mask layer (e.g., an etch mask) over dielectric layer 250 and etching exposed portions of dielectric layer 250. In some embodiments, forming at least one electrically conductive layer in the source/drain contact opening includes forming a metal silicide layer over the epitaxial source/drain, depositing a barrier/liner layer that partially fills the source/drain contact opening, depositing a metal layer over the barrier/liner layer that fills remainders of the source/drain contact opening, and performing a planarization process to remove portions of the barrier/liner layer and/or the metal layer that are disposed over the top of dielectric layer 250 and/or gate structures 230. In some embodiments, one or more insulation layers may be formed in the source/drain contact opening and processed to form contact spacers, such as dielectric layers and/or air gaps, along sidewalls of electrically conductive portions of the source/drain contact (e.g., barrier layer and/or bulk metal layer).

In some embodiments, device 200 is an n-type transistor, and portions of the gate stack are formed at the same time as a p-type transistor. For example, processing may include forming interfacial layer 262 and high-k dielectric layer 264 at the same time as an interfacial layer and a high-k dielectric layer of a gate stack of the p-type transistor; masking a p-type device region that includes the p-type transistor with a first mask layer (e.g., a hard mask layer and/or a photoresist layer) and forming work function layer 272, capping layer 276, and capping layer 278; removing the first mask layer; masking an n-type device region that includes the n-type transistor (e.g., device 200) with a second mask layer (e.g., a hard mask layer and/or a photoresist layer) and forming a work function layer (e.g., a P-WFM layer) and/or a cap of the gate stack of the p-type transistor; removing the second mask layer; and forming bulk layer 282 at the same time as bulk layer of the p-type transistor (e.g., forming a bulk layer (e.g., bulk layer 282) in both the p-type device region and the n-type device region). In such embodiments, the work function layer and the cap of the n-type transistor are formed before the work function layer of the p-type transistor. In some embodiments, the work function layer and the cap of the n-type transistor are formed after the work function layer of the p-type transistor. For example, processing may include forming interfacial layer 262 and high-k dielectric layer 264 at the same time as an interfacial layer and a high-k dielectric layer of a gate stack of the p-type transistor; masking an n-type device region that includes the n-type transistor (e.g., device 200) with a first mask layer (e.g., a hard mask layer and/or a photoresist layer) and forming a work function layer (e.g., a P-WFM layer) and/or a cap of the gate stack of the p-type transistor; removing the first mask layer; masking a p-type device region that includes the p-type transistor with a second mask layer (e.g., a hard mask layer and/or a photoresist layer) and forming work function layer 272, capping layer 276, and capping layer 278; removing the second mask layer; and forming bulk layer 282 at the same time as bulk layer of the p-type transistor. The present disclosure contemplates various process flows that implement the gate fabrication methods therein.

The present disclosure provides for many different embodiments. The gate stacks disclosed herein may be implemented in a variety of device types. For example, the gate stacks described herein are suitable for planar field-effect transistors (FETs), multigate transistors, such as FinFETs, GAA transistors, omega-gate (Ω-gate) devices, pi-gate (Π-gate) devices, fork-sheet gate devices, or a combination thereof, as well as strained-semiconductor devices, silicon-on-insulator (SOI) devices, partially-depleted SOI devices, fully-depleted SOI devices, other devices, or a combination thereof. The gate stacks described herein are further suitable for stacked transistor devices, such as complementary field effect transistors (CFETs).

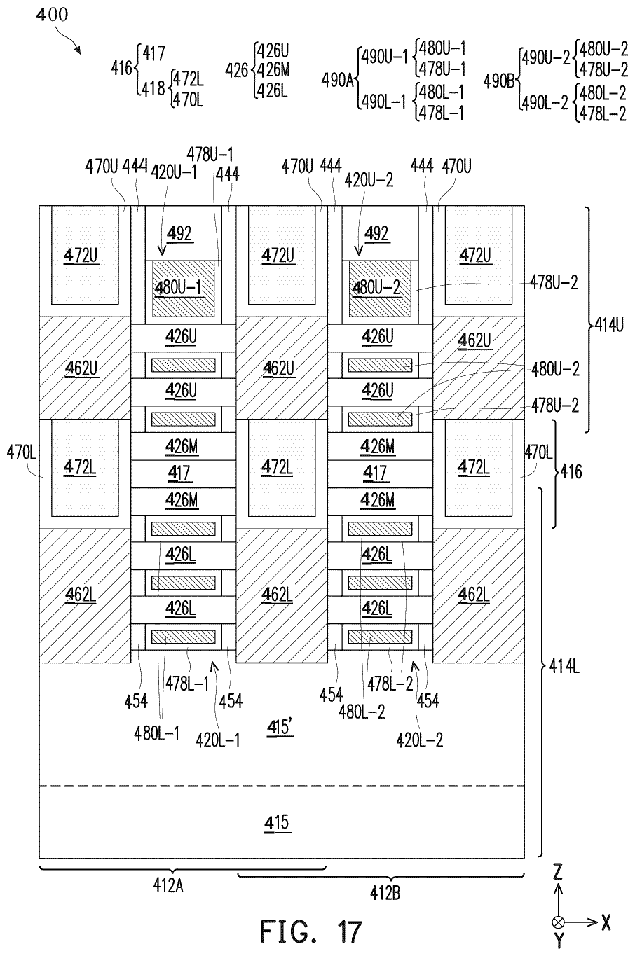

FIG. 17 is a cross-sectional view of a stacked device structure 400, in portion or entirety, that may implement the gate stacks described herein, according to various aspects of the present disclosure. Stacked device structure 400 includes a device stack 412A and a device stack 412B. Device stack 412A and device stack 412B each include a respective upper device 414U vertically stacked over a respective lower device 414L. Device 414U and device 414L are disposed over a substrate 415, and an isolation structure 416 is disposed between and separates device 414U and device 414L. Isolation structure 416 includes isolation structures 417 and isolation structures 418. In some embodiments, device 414U and device 414L are stacked back-to-front. For example, a backside of device 414U is bonded and/or attached to a frontside of device 414L. FIG. 17 has been simplified for the sake of clarity to better understand the inventive concepts of the present disclosure. Additional features may be added in stacked device structure 400, and some of the features described below may be replaced, modified, or eliminated in other embodiments of stacked device structure 400.

Devices 414U and devices 414L include at least one electrically functional device. For example, device stack 412A is a transistor stack having an upper transistor 420U-1 and a lower transistor 420L-1, and device stack 412B is a transistor stack having an upper transistor 420U-2 and a lower transistor 420L-2. Transistor 420U-1 may be separated and/or electrically isolated from transistor 420L-1 by isolation structure 416, and transistor 420U-2 may be separated and/or electrically isolated from transistor 420L-2 by isolation structure 416. In the depicted embodiment, transistor 420U-1 and transistor 420L-1 are of an opposite conductivity type, and transistor 420U-2 and transistor 420L-2 are of an opposite conductivity type. For example, transistor 420U-1 and transistor 420U-2 are n-type transistors, and transistor 420L-1 and transistor 420L-2 are p-type transistors, or vice versa. In such embodiments, transistor 420U-1 and transistor 420L-1 form a first CFET, and transistor 420U-2 and transistor 420L-2 form a second CFET. In some embodiments, transistor 420U-1 and transistor 420L-1 are of a same conductivity type, and/or transistor 420U-2 and transistor 420L-2 are of a same conductivity type. For example, transistor 420U-1 and transistor 420L-1 and/or transistor 420U-2 and transistor 420L-2 are both n-type transistors or both p-type transistors.

Devices 414U include various features and/or components, such as semiconductor layers 426U, semiconductor layers 426M, gate spacers 444, inner spacers 454, epitaxial source/drains 462U, CESL 470U, ILD layer 472U, gate dielectrics (e.g., a gate dielectric 478U-1 and a gate dielectric 478L-1), gate electrodes (e.g., a gate electrode 480U-1 and a gate electrode 480L-1), and hard masks 492. Gate dielectric 478U-1 and gate electrode 480U-1 collectively form an upper gate stack 490U-1, and gate dielectric 478L-1 and gate electrode 480L-1 collectively form a lower gate stack 490L-1. Gate stack 490U-1 and gate stack 490L-1 are collectively referred to as a gate 490A of device stack 412A, and gate 490A may provide a metal gate or a high-k/metal gate of the first CFET. Gate stack 490U-1 is separated from gate stack 490L-1 by a respective isolation structure 417 (and semiconductor layers 426M in the depicted embodiment), and epitaxial source/drains 462U of devices 414U are separated from epitaxial source/drains 462L of devices 414L by isolation structures 418.

Devices 414L include various features and/or components, such as mesas 415′ (e.g., extensions of substrate 415), semiconductor layers 426L, semiconductor layers 426M, substrate isolation structures 28, inner spacers 454, epitaxial source/drains 462L, a CESL 470L, an ILD layer 472L, gate dielectrics (e.g., a gate dielectric 478U-2 and a gate dielectric 478L-2), and gate electrodes (e.g., a gate electrode 480U-2 and a gate electrode 480L-2). Gate dielectric 478U-2 and a gate electrode 480U-2 collectively form an upper gate stack 490U-2, and gate dielectric 478L-2 and gate electrode 480L-2 collectively form a lower gate stack 490L-2. Gate stack 490U-2 and gate stack 490L-2 are collectively referred to as a gate 490B of device stack 412B, and gate 490B may provide a metal gate or a high-k/metal gate of the second CFET. Gate stack 490U-2 is separated from gate stack 490L-2 by a respective isolation structure 417 (and semiconductor layers 426M), and epitaxial source/drains 462L of devices 414L are separated from epitaxial source/drains 462U of devices 414L by isolation structures 418.

Transistor 420L-1 and transistor 420L-2 are configured as GAA transistors. For example, each of transistor 420L-1 and transistor 420L-2 has two channels (for example, nanowires, nanosheets, nanobars, etc.) provided by semiconductor layers 426L (also referred to as channel layers or channels), which are suspended over substrate 415 and extend between respective source/drains, such as epitaxial source/drains 462L. In some embodiments, transistor 420L-1 and/or transistor 420L-2 includes more or less channels (and thus more or less semiconductor layers 426L). Transistor 420L-1 has gate stack 490L-1 disposed over its semiconductor layers 426L and between its epitaxial source/drains 462L, and transistor 420L-2 has gate stack 490L-2 disposed over its semiconductor layers 426L and between its epitaxial source/drains 462L. Along a gate widthwise direction, gate stack 490L-1 and gate stack 490L-2 are over a respective top semiconductor layer 426L, between respective semiconductor layers 426L, and between a respective bottom semiconductor layer 426L and substrate 415 (e.g., mesa 415′ thereof). Along a gate lengthwise direction, gate stack 490L-1 and gate stack 490L-2 may wrap and/or surround respective semiconductor layers 426L. During operation of the GAA transistors, current may flow through respective semiconductor layers 426L and between respective epitaxial source/drains 462L. In the depicted embodiment, transistor 420L-1 and transistor 420L-2 have a common epitaxial source/drain 462L, such as middle epitaxial source/drain 462L. In some embodiments, transistor 420L-1 and transistor 420L-2 do not have a common epitaxial source/drain 462L. Each of transistor 420L-1 and transistor 420L-2 further has semiconductor layers 426M (also referred to as dummy channel layers or dummy channels) suspended over substrate 415 and extending between respective isolation structures 418. A respective isolation structure 417 is disposed between semiconductor layers 426M of transistor 420L-1 and transistor 420U-1, and a respective isolation structure 417 is disposed between semiconductor layers 426M of transistor 420L-2 and transistor 420U-2. Further, each of transistor 420L-1 and transistor 420L-2 has inner spacers 454 disposed between its gate stack (e.g., gate stack 490L-1 or gate stack 490L-2) and its epitaxial source/drains 462L.

Transistor 420U-1 and transistor 420U-2 are also configured as GAA transistors. For example, each of transistor 420U-1 and transistor 420U-2 has two channels (for example, nanowires, nanosheets, nanobars, etc.) provided by semiconductor layers 426U (also referred to as channel layers or channels), which are suspended over substrate 415 and extend between respective source/drains, such as epitaxial source/drains 462U. In some embodiments, transistor 420U-1 and/or transistor 420U-2 includes more or less channels (and thus more or less semiconductor layers 426U). Transistor 420U-1 has gate stack 490U-1 disposed over its semiconductor layers 426U and between its epitaxial source/drains 462U, and transistor 420U-2 has gate stack 490U-2 disposed over its semiconductor layers 426U and between its epitaxial source/drains 462U. Along a gate widthwise direction, gate stack 490U-1 and gate stack 490U-2 are over a respective top semiconductor layer 426U, between respective semiconductor layers 426U, and between a respective bottom semiconductor layer 426U and a respective semiconductor layer 426M. Along a gate lengthwise direction, gate stack 490U-1 and gate stack 490U-2 may wrap and/or surround respective semiconductor layers 426U. During operation of the GAA transistors, current may flow through respective semiconductor layers 426U and between respective epitaxial source/drains 462U. In the depicted embodiment, transistor 420U-1 and transistor 420U-2 have a common epitaxial source/drain 462U, such as middle epitaxial source/drain 462U. In some embodiments, transistor 420U-1 and transistor 420U-2 do not have a common epitaxial source/drain 462U. Further, each of transistor 420U-1 and transistor 420U-2 has gate spacers 444 disposed along sidewalls of an upper portion of its gate stack (e.g., gate stack 490L-1 or gate stack 490L-2), inner spacers 454 disposed between its gate stack and its epitaxial source/drains 462U, and hard masks 492 disposed over its gate stack and between its gate spacers 444. Hard masks 492 may be considered a portion of the gate stacks.

Isolation structure 416 has isolation structures 417 and isolation structures 418 between channel regions and source/drain regions, respectively, of devices 414L and devices 414U. For example, isolation structures 417 are between channel regions of lower transistors (e.g., transistor 420L-1) and channel regions of upper channels (e.g., transistor 420U-1) (e.g., between channels and/or gates thereof), and isolation structures 418 are between source/drain regions of lower transistors (e.g., transistor 420L-1) and source/drain regions of upper channels (e.g., transistor 420U-1). In the depicted embodiment, isolation structures 417 are between semiconductor layers 426M of lower transistors and upper transistors, and isolation structures 418 are between epitaxial source/drains 462L of lower transistors and epitaxial source/drains 462U of upper transistors. Accordingly, isolation structures 417 may provide electrical isolation of channels and/or gates of stacked devices, and isolation structures 418 may provide electrical isolation of source/drains of stacked devices. Isolation structures 417 and isolation structures 418 may include a single layer or multiple layers. Isolation structures 417 and isolation structures 418 include a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). Isolation structures 417 and isolation structures 418 may include the same or different materials and/or configurations. In the depicted embodiment, a thickness of isolation structures 417 is less than a thickness of isolation structures 418, and a configuration of isolation structures 417 is different than a configuration of isolation structures 418. In some embodiments, isolation structures 418 include CESL 470L and ILD layer 472L, such as depicted (i.e., each isolation structure 418 is formed by a respective portion of CESL 470L and a respective portion of ILD layer 472L).

Substrate 415 may be similar to substrate 202 described above, mesa 415′ may be similar to mesa 202′ described above, and semiconductor layers 426U, semiconductor layers 426M, and semiconductor layers 426L may be similar to semiconductor layers 220, 220′ described above. For example, in the depicted embodiment, substrate 415, mesa 415′, semiconductor layers 426U, semiconductor layers 426M, and semiconductor layers 426L include silicon. In some embodiments, semiconductor layers 426U and semiconductor layers 426L include different semiconductor materials, such as silicon and silicon germanium, respectively, or vice versa. In such embodiments, semiconductor layers 426M of upper transistors and semiconductor layers 426M of lower transistors may include different materials. For ease of description herein, semiconductor layers 426U, semiconductor layers 426M, and semiconductor layers 426L may be referred to collectively as semiconductor layers 426.

Gate spacers 444 are disposed along sidewalls of top portions of upper gate stacks (e.g., gate stack 490U-1 and gate stack 490U-2), inner spacers 454 are disposed under gate spacers 444 along sidewalls of upper gate stacks 490U and/or lower gate stacks (e.g., gate stack 490L-1 and gate stack 490L-2), and fin/mesa spacers may be disposed along sidewalls of mesas 415′. Inner spacers 454 are between semiconductor layers 426U, between semiconductor layers 426L, between bottom semiconductor layers 426U and semiconductor layers 426M, between top semiconductor layers 426L and semiconductor layers 426M, and between bottom semiconductor layers 426M and mesas 415′. Gate spacers 444 may be similar to gate spacers 240 described above, and inner spacers 454 may be similar to inner spacers 224 described above.

Each of gate 490A and gate 490B is disposed between respective epitaxial source/drain stacks. Each epitaxial source/drain stack includes a respective epitaxial source/drain 462U, a respective epitaxial source/drain 462L, and a respective insolation structure 418 therebetween. Epitaxial source/drains 462L and epitaxial source/drains 462U may be similar to epitaxial source/drains 225 described above. Epitaxial source/drains 462L and epitaxial source/drains 462U may have the same or different compositions and/or materials depending on configurations of their respective transistors. For example, where upper transistors are NFETs and lower transistors are PFETs, such as in the depicted embodiment, epitaxial source/drains 462U may include silicon doped with phosphorous and/or carbon, and epitaxial source/drains 462L may include silicon germanium doped with boron.

ILD layer 472U and ILD layer 472L may be similar to ILD layer 254 described above, and CESL 470L and CESL 470U may be similar to CESL 252 described above. Gate dielectric 478U-1, gate dielectric 478L-1, gate dielectric 478U-2, and gate dielectric 478L-2 each include at least one dielectric gate layer, such as interfacial layers and/or high-k dielectric layers, which are described further below. Gate electrode 480U-1, gate electrode 480L-1, gate electrode 480U-2, and gate electrode 480L-2 each include at least one electrically conductive gate layer, such as a work function layer, a metal fill (bulk) layer, additional layers (e.g., a barrier layer and/or one or more capping layers), or a combination thereof. Gate dielectric 478U-1, gate dielectric 478L-1, gate dielectric 478U-2, gate dielectric 478L-2, or a combination thereof may be similar to gate dielectric 230A described above. Gate electrode 480U-1, gate electrode 480L-1, gate electrode 480U-2, gate electrode 480L-2, or a combination thereof may be similar to gate dielectric 230A described above. In some embodiments, a composition and/or a configuration of gate dielectric 478U-1 and gate dielectric 478U-2 is different than a composition and/or a configuration of gate dielectric 478L-1 and gate dielectric 478L-2. In some embodiments, a composition and/or a configuration of gate electrode 480U-1 and gate electrode 480U-2 is different than a composition and/or a configuration of gate electrode 480L-1 and gate electrode 480L-2. For example, gate electrode 480U-1 and gate electrode 480U-2 may be configured as gate electrode 230B, and gate electrode 480L-1 and gate electrode 480L-2 may be configured differently than gate electrode 230B. In some embodiments, the work function layer of gate electrode 480U-1 and gate electrode 480U-2 may be an n-type work function layer, and the work function layer of gate electrode 480L-1 and gate electrode 480L-2 may be a p-type work function layer. In some embodiments, gate electrode 480U-1, gate electrode 480L-1, gate electrode 480U-2, and gate electrode 480L-2 have a same type of work function layer (e.g., n-metal or p-metal). In some embodiments, gate electrode 480U-1 and gate electrode 480U-2 each include a first work function layer, and gate electrode 480L-1 and gate electrode 480L-2 each include a second work function layer. The first work function layer and the second work function layer may include different type work function layers (e.g., p-metal and n-metal, respectively).

Hard masks 492 include a material that is different than ILD layer 472U and/or subsequently formed ILD layers to achieve etch selectivity during subsequent etching processes. In some embodiments, hard masks 492 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or a combination thereof. In some embodiments, hard masks 492 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or a combination thereof.

An exemplary method includes forming a first semiconductor layer and a second semiconductor layer over a substrate. The first semiconductor layer is disposed over the second semiconductor layer, and a space is between the first semiconductor layer and the second semiconductor layer. The method further includes forming a gate dielectric over the first semiconductor layer and the second semiconductor layer. The gate dielectric partially fills the space between the first semiconductor layer and the second semiconductor layer. The method further includes forming a work function layer over the gate dielectric. The work function layer fills a remainder of the space between the first semiconductor layer and the second semiconductor layer. The method further includes forming a cap over the work function layer. In some embodiments, the method further includes forming a metal fill layer over the cap.

In some embodiments, an air gap forms in the work function layer in the space between the first semiconductor layer and the second semiconductor layer. In some embodiments, forming the work function layer includes depositing an electrically conductive material that includes titanium, aluminum, and carbon. In some embodiments, forming the work function layer provides a first portion of the work function layer along a bottom of the first semiconductor layer with a first thickness that is less than about two times a second thickness of a second portion of the work function layer along a top of the first semiconductor layer.

In some embodiments, forming the cap includes forming a metal nitride layer over the work function layer and forming a silicon-comprising layer over the metal nitride layer. In some embodiments, forming the metal nitride layer includes forming a first metal nitride sublayer over the work function layer and, after breaking vacuum, forming a second metal nitride sublayer. In some embodiments, the first semiconductor layer and the second semiconductor layer form a channel stack, along a first direction, the cap is disposed over a top of the channel stack, and along a second direction, the cap wraps the channel stack.

In some embodiments, forming the work function layer includes depositing an electrically conductive material having a thickness around the first semiconductor layer and the second semiconductor layer. In the space between the first semiconductor layer and the second semiconductor layer, the electrically conductive material having the thickness around the first semiconductor layer merges with the electrically conductive material having the thickness around the second semiconductor layer merge. In such embodiments, forming the work function layer further includes continuing the depositing to increase the thickness of the electrically conductive material along sidewalls of the first semiconductor layer, sidewalls of the second semiconductor layer, and a top of the first semiconductor layer.

In some embodiments, the method includes removing a dummy gate to form a gate opening that exposes a semiconductor stack and performing a channel release process to remove third semiconductor layers from the semiconductor stack, thereby suspending the first semiconductor layer over the second semiconductor layer and the second semiconductor layer over the substrate.

An exemplary method for forming a gate stack of a transistor includes forming a first interfacial layer around a first channel layer and a second interfacial layer around a second channel layer. A channel stack includes the first channel layer disposed over the second channel layer. The first interfacial layer partially fills a space between the first channel layer and the second channel layer, and the second interfacial layer partially fills the space between the first channel layer and the second channel layer. The method includes forming a first high-k dielectric layer over the first interfacial layer and around the first channel layer and a second high-k dielectric layer over the second interfacial layer and around the second channel layer. The first high-k dielectric layer partially fills the space between the first channel layer and the second channel layer, and the second high-k dielectric layer partially fills the space between the first channel layer and the second channel layer. The method includes forming a work function layer around the first channel layer and the second channel layer. The work function layer fills a remainder of the space between the first channel layer and the second channel layer.

The work function layer may be formed by depositing a work function material until a first portion of the work function material that forms over the first high-k dielectric layer and around the first channel layer merges with a second portion of the work function material that forms over the second high-k dielectric layer and around the second channel layer. The first portion of the work function material merges with the second portion of the work function material in the space between the first channel layer and the second channel layer. The work function layer may further be formed by continuing the depositing of the work function material to increase a thickness of the first portion of the work function material and the second portion of the work function material. In some embodiments, in the space between the first channel layer and the second channel layer, ends of the first portion of the work function material and the second portion of the work function material merge before centers thereof, thereby forming an air gap between the first portion of the work function material and the second portion of the work function material in the space between the first channel layer and the second channel layer. In some embodiments, the work function layer is a titanium aluminum carbide layer, and an aluminum content of the work function layer is about 25 at % to about 33 at %.

The method further includes forming a cap over the work function layer. The cap wraps the channel stack. Forming the cap may include forming a first metal nitride layer over the work function layer and forming a second metal nitride layer over the first metal nitride layer. The second metal nitride layer may be formed after breaking vacuum. Forming the cap may further include forming a silicon-comprising layer over the second metal nitride layer. In some embodiments, the first metal nitride layer is a first titanium nitride layer, and the second metal nitride layer is a second titanium nitride layer. In some embodiments, after forming the cap, an outer region of the gate stack has a first oxygen content, an inner region of the gate stack has a second oxygen content, a ratio of the first oxygen content to the second oxygen content is about 1 to about 1.25, the inner region of the gate stack fills the space between the first channel layer and the second channel layer, and the outer region of the gate stack is not in the space between the first channel layer and the second channel layer.

In some embodiments, a gate opening exposes the first channel layer and the second channel layer, and the first interfacial layer, the first high-k dielectric layer, the work function layer, and the cap partially fill a top of the gate opening above the first channel layer. In such embodiments, the method may further include forming a bulk/fill layer over the cap. The bulk/fill layer may fill a remainder of the top of the gate opening, and the bulk/fill layer wraps the channel stack. In some embodiments, the transistor is an n-type transistor, and the work function layer is a n-type work function metal layer.

An exemplary transistor includes a first channel layer, a second channel layer, and a gate stack. The gate stack includes a gate dielectric disposed around the first channel layer and the second channel layer. The gate dielectric includes an interfacial layer and a high-k dielectric layer disposed over the interfacial layer. The gate stack further includes a gate electrode disposed over the gate dielectric. The gate electrode is around the first channel layer and the second channel layer. The gate electrode includes a work function layer disposed over the high-k dielectric layer. The work function layer is around the first channel layer and the second channel layer. The gate electrode further includes a cap disposed over the work function layer. The cap includes a metal nitride layer disposed over the work function layer and a silicon layer disposed over the metal nitride layer. The gate dielectric and the work function layer fill a space between the first channel layer and the second channel layer. An outer region of the gate stack has a first oxygen content, an inner region of the gate stack has a second oxygen content, and a ratio of the first oxygen content to the second oxygen content is about 1 to about 1.25. Further, a first thickness of the work function layer in the outer region of the gate stack is greater than a second thickness of the work function layer in the inner region of the gate stack. In some embodiments, the work function layer includes titanium, aluminum, and carbon. In some embodiments, an aluminum content of the work function layer is about 25 atomic percent (at %) and about 33 at %. In some embodiments, an air gap is in the work function layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stack of semiconductor layers that extend from a first source/drain to a second source/drain along a first direction, wherein the semiconductor layers are stacked along a second direction different from the first direction and gaps are between and separate the semiconductor layers from one another along the second direction;
depositing a high-k dielectric layer over the stack of the semiconductor layers, wherein the depositing of the high-k dielectric layer is configured to partially fill the gaps between the semiconductor layers with the high-k dielectric layer;
depositing a titanium aluminum carbide layer over the high-k dielectric layer, wherein the depositing of the titanium aluminum carbide layer is configured to fill remainders of the gaps between the semiconductor layers with the titanium aluminum carbide layer; and
depositing a titanium nitride layer over the titanium aluminum carbide layer and depositing a silicon layer over the titanium nitride layer, wherein the titanium nitride layer and the silicon layer wrap the stack of the semiconductor layers along a third direction, wherein the third direction is different from the first direction and the second direction.

2. The method of claim 1, wherein the depositing of the titanium nitride layer is configured to provide the titanium nitride layer with an oxygen-comprising region therein.

3. The method of claim 2, wherein the depositing of the titanium nitride layer includes breaking vacuum to provide the oxygen-comprising region therein.

4. The method of claim 2, further comprising providing the oxygen-comprising region therein with a thickness of about 0.1 nm to about 0.2 nm.

5. The method of claim 1, wherein the depositing of the titanium aluminum carbide layer is configured to provide the titanium aluminum carbide layer with an aluminum content that is about 25 atomic percent (at %) to about 33 at %.

6. The method of claim 1, further comprising depositing a metal layer over the silicon layer that also wraps the stack of the semiconductor layers along the third direction.

7. The method of claim 1, wherein, during the depositing of the titanium aluminum carbide layer, first portions of the titanium aluminum carbide layer deposited in the gaps between the semiconductor layers merge together before second portions of the titanium aluminum carbide layer deposited in the gaps between the semiconductor layers merge together, such that air gaps form within the titanium aluminum carbide layer.

8. The method of claim 1, wherein the depositing of the silicon layer is configured to deposit silicon over the titanium nitride layer.

9. The method of claim 1, wherein the depositing of the silicon layer is configured to deposit polysilicon over the titanium nitride layer.

10. The method of claim 1, wherein the depositing of the silicon layer is configured to deposit amorphous silicon over the titanium nitride layer.

11. A method for forming a gate stack of a transistor, the method comprising:
sequentially depositing a high-k dielectric layer over a stack of semiconductor layers, a titanium aluminum carbide layer over the high-k dielectric layer, a titanium nitride layer having an oxygen-comprising region therein over the titanium aluminum carbide layer, a silicon layer over the titanium nitride layer, and a metal layer over the silicon layer; and
configuring the depositing to provide:
a first portion of the gate stack over a topmost semiconductor layer of the stack of the semiconductor layers that includes the high-k dielectric layer, the titanium aluminum carbide layer, the titanium nitride layer, the silicon layer, and the metal layer sequentially stacked over the topmost semiconductor layer along a gate height direction,
second portions of the gate stack between respective semiconductor layers of the stack of the semiconductor layers along the gate height direction, wherein the second portions include the titanium aluminum carbide layer disposed between respective portions of the high-k dielectric layer,
third portions of the gate stack over sidewalls of the semiconductor layers, wherein the third portions include the high-k dielectric layer, the titanium aluminum carbide layer, the titanium nitride layer, the silicon layer, and the metal layer sequentially stacked over the sidewalls of the semiconductor layers along a gate length direction, and
a ratio of an oxygen content of the third portions of the gate stack to an oxygen content of the second portions of the gate stack of about 1 to about 1.25.

12. The method of claim 11, further comprising configuring the depositing to provide a ratio of an oxygen content of the first portion of the gate stack to the oxygen content of the second portions of the gate stack of about 1 to about 1.25.

13. The method of claim 11, further comprising configuring the depositing to provide the titanium aluminum carbide layer with an aluminum content that is about 25 atomic percent (at %) to about 33 at %.

14. The method of claim 11, further comprising configuring the depositing of the titanium aluminum carbide layer to continue depositing titanium aluminum carbide material over the topmost semiconductor layer and along sidewalls of the semiconductor layers after filling spaces between the semiconductor layers along the gate height direction.

15. The method of claim 11, wherein the depositing of the titanium nitride layer having the oxygen-comprising region therein includes:
depositing a first titanium nitride sublayer over the titanium aluminum carbide layer; and
after breaking vacuum, forming a second titanium nitride sublayer over the first titanium nitride sublayer, wherein the oxygen-comprising region is between the first titanium nitride sublayer and the second titanium nitride sublayer.

16. The method of claim 11, further comprising configuring the depositing of the titanium nitride layer to provide the oxygen-comprising region of the titanium nitride layer with a thickness of about 0.1 nm to about 0.2 nm.

17. The method of claim 11, wherein air gaps form within the titanium aluminum carbide layer of the second portions of the gate stack during the depositing.

18. A transistor comprising:
a stack of semiconductor layers that extend from a first source/drain to a second source/drain along a first direction, wherein the semiconductor layers are stacked along a second direction different from the first direction; and
a gate stack disposed between the first source/drain and the second source/drain along the first direction, wherein the gate stack includes:
a high-k dielectric layer, a titanium aluminum carbide layer disposed over the high-k dielectric layer, a titanium nitride layer disposed over the titanium aluminum carbide layer, a silicon layer disposed over the titanium nitride layer, and a metal layer disposed over the silicon layer,
wherein a first portion of the gate stack is disposed over a topmost semiconductor layer of the stack of the semiconductor layers, wherein the first portion includes the high-k dielectric layer, the titanium aluminum carbide layer, the titanium nitride layer, the silicon layer, and the metal layer sequentially stacked over the topmost semiconductor layer,
wherein second portions of the gate stack are disposed between respective semiconductor layers of the stack of the semiconductor layers along the second direction, wherein the second portions include the titanium aluminum carbide layer disposed between respective portions of the high-k dielectric layer, and
wherein the titanium nitride layer includes an oxygen-comprising region.

19. The transistor of claim 18, wherein:
an aluminum content of the titanium aluminum carbide layer is about 25 atomic percent (at %) to about 33 at %; and
a thickness of the oxygen-comprising region is about 0.1 nm to about 0.2 nm.

20. The transistor of claim 18, wherein:
third portions of the gate stack are disposed over sidewalls of the semiconductor layers, wherein the third portions include the high-k dielectric layer, the titanium aluminum carbide layer, the titanium nitride layer, the silicon layer, and the metal layer sequentially stacked over the sidewalls of the semiconductor layers, and
a ratio of an oxygen content of the third portions of the gate stack to an oxygen content of the second portions of the gate stack is about 1 to about 1.25.
